(19) United States
(12) Patent Application Publication
(10) Pub. No.: US 2026/0313457 A1
(43) Pub. Date: Oct. 8, 2026

(54) ENCODING AND DECODING TECHNIQUES ASSOCIATED WITH SEMANTIC ENCODING

(71) Applicant: QUALCOMM Incorporated, San Diego, CA (US)

(72) Inventors: Chenxi Hao, Beijing (CN); Ruiming Zheng, Beijing (CN); Chao Wei, Beijing (CN); Juan Zhang, Beijing (CN); Rui Hu, Beijing (CN); Taesang Yoo, San Diego, CA (US); Hao Xu, Beijing (CN)

(21) Appl. No.: 19/483,524

(22) PCT Filed: Jun. 23, 2023
(86) PCT No.: PCT/CN2023/102009

§ 371 Date: Nov. 11, 2025

(51) Int. Cl. H04W 28/06; H04W 28/02; H04W 72/543

(52) U.S. Cl. CPC H04W 28/06; H04W 28/0252; H04W 72/543

(57) ABSTRACT

Various aspects of the present disclosure relate to techniques that enable simplified encoding operations, decoding operations, or both, by a wireless communication device, such as a user equipment (UE) or a base station. In an example, the wireless communication device may use a medium access control layer (MAC) to inspect packets. If two inspected packets indicate different encoding processes, including at least one semantic encoding process, the MAC layer may avoid assigning the packets to the same MAC packet data unit (PDU) (also referred to as multiplexing the packets) and may instead assign the packets to different MAC PDUs. In an alternative implementation of the first example, packets associated with different encoding processes may be assigned to different radio bearers, and the MAC layer may avoiding assigning the packets to the same MAC PDU in accordance with the packets being associated with the different radio bearers.

### TECHNICAL FIELD

Aspects of the relate generally to wireless communication systems, and more particularly, to encoding and decoding techniques associated with semantic encoding.

### DESCRIPTION OF THE RELATED TECHNOLOGY

Wireless communications systems are widely deployed to provide various types of communication content such as voice, video, packet data, messaging, broadcast, and so on. A wireless multiple-access communications system may include a number of base stations or network access nodes, each simultaneously supporting communication for multiple communication devices, which may be otherwise known as user equipment (UE). These systems may be capable of supporting communication with multiple UEs by sharing the available system resources (such as time, frequency, and power). Examples of such multiple-access systems include fourth generation (4G) systems such as Long Term Evolution (LTE) systems, LTE-Advanced (LTE-A) systems, or LTE-A Pro systems, and fifth generation (5G) systems which may be referred to as New Radio (NR) systems. These systems may employ technologies such as code division multiple access (CDMA), time division multiple access (TDMA), frequency division multiple access (FDMA), orthogonal frequency division multiple access (OFDMA), or discrete Fourier transform spread orthogonal frequency division multiplexing (DFT-S-OFDM).

Wireless communication systems may use encoders and decoders to encode and decode data. Some techniques for encoding and decoding data include semantic-based techniques. Semantic-based techniques may encode and decode data based at least in part on a content type of the data, such as by encoding data representing an image differently than data representing a song or a video. Semantic-based techniques may also include or use joint source and channel coding (JSCC) techniques to perform a single coding process for both source coding and channel coding, which may potentially simplify operation and hardware of encoders and decoders. In some devices, some stages of semantic encoding may include generating side information associated with data, generating a feature probability associated with the side information, and JSCC-encoding the data using the feature probability.

Applying such techniques may pose some difficulties in the context of some wireless communication systems. For example, a wireless communication protocol may specify various processing operations for data that is to be transmitted. The processing operations may be associated with multiple different layers of a protocol stack, such as a service data adaption protocol (SDAP) layer, a packet data convergence protocol (PDCP) layer, a radio link control (RLC) layer, a medium access control (MAC) layer, and a physical (PHY) layer. In some circumstances, such operations may result in different types of data being aggregated (or “mixed” or “packaged”), which may be difficult or infeasible to integrate with semantic encoding techniques (which may rely on a particular content type of data). As a result, semantic-based techniques are not widely used in wireless communications systems.

### SUMMARY

The following summarizes some aspects of the present disclosure to provide a basic understanding of the discussed technology. This summary is not an extensive overview of all contemplated features of the disclosure, and is intended neither to identify key or critical elements of all aspects of the disclosure nor to delineate the scope of any or all aspects of the disclosure. Its sole purpose is to present some concepts of one or more aspects of the disclosure in summary form as a prelude to the more detailed description that is presented later.

One innovative aspect of the subject matter described in this disclosure can be implemented in a wireless communication device that includes a processing system. The processing system includes processor circuitry and memory circuitry that stores code and is coupled with the processor circuitry. The processing system is configured to cause the wireless communication device to transmit, in accordance with inspecting one or more first packets using a medium access control (MAC) layer to identify a first flag indicating a first encoding process, a first transport block (TB) that includes the one or more first packets. The first encoding process is a semantic encoding process. The processing system is further configured to cause the wireless communication device to transmit, in accordance with inspecting one or more second packets using the MAC layer to identify a second flag indicating a second encoding process, a second TB that includes the one or more second packets. The second encoding process is a semantic or non-semantic encoding process.

Another innovative aspect of the subject matter described in this disclosure can be implemented in a method for wireless communication by a wireless communication device. The method includes transmitting, in accordance with inspecting one or more first packets using a MAC layer to identify a first flag indicating a first encoding process, a first TB that includes the one or more first packets. The first encoding process is a semantic encoding process. The method further includes transmitting, in accordance with inspecting one or more second packets using the MAC layer to identify a second flag indicating a second encoding process, a second TB that includes the one or more second packets. The second encoding process is a semantic or non-semantic encoding process.

Another innovative aspect of the subject matter described in this disclosure can be implemented in a wireless communication device that includes a processing system. The processing system includes processor circuitry and memory circuitry that stores code and is coupled with the processor circuitry. The processing system is configured to cause the wireless communication device to transmit, in accordance with one or more first packets being associated with a first radio bearer, a first TB that includes the one or more first packets and to transmit, in accordance with one or more second packets being associated with a second radio bearer, a second TB that includes the one or more second packets. The one or more first packets are associated with a first encoding process that is a semantic encoding process, and the one or more second packets are associated with a second encoding process that is a semantic or non-semantic encoding process.

Another innovative aspect of the subject matter described in this disclosure can be implemented in a method for wireless communication by a wireless communication device. The method includes transmitting, in accordance with one or more first packets being associated with a first radio bearer, a first TB that includes the one or more first packets. The one or more first packets are associated with a first encoding process that is a semantic encoding process. The method further includes transmitting, in accordance with one or more second packets being associated with a second radio bearer, a second TB that includes the one or more second packets. The one or more second packets are associated with a second encoding process that is a semantic or non-semantic encoding process.

Other aspects, features, and implementations of the present disclosure will become apparent to a person having ordinary skill in the art, upon reviewing the following description of specific, example implementations of the present disclosure in conjunction with the accompanying figures. While features of the present disclosure may be described relative to particular implementations and figures below, all implementations of the present disclosure can include one or more of the advantageous features described herein. In other words, while one or more implementations may be described as having particular advantageous features, one or more of such features may also be used in accordance with the various implementations of the disclosure described herein. In similar fashion, while example implementations may be described below as device, system, or method implementations, such example implementations can be implemented in various devices, systems, and methods.

### BRIEF DESCRIPTION OF THE DRAWINGS

A further understanding of the nature and advantages of the present disclosure may be realized by reference to the following drawings. In the appended figures, similar components or features may have the same reference label. Further, various components of the same type may be distinguished by following the reference label by a dash and a second label that distinguishes among the similar components. If just the first reference label is used in the specification, the description is applicable to any one of the similar components having the same first reference label irrespective of the second reference label.

FIG. 1 is a block diagram illustrating details of an example wireless communication system according to one or more aspects.

FIG. 2 is a block diagram illustrating examples of a base station and a user equipment (UE) according to one or more aspects.

FIG. 3 is a block diagram of an example semantic encoding and decoding system that supports one or more of packet inspection using a medium access control (MAC) layer for a semantic encoding process, associating a data segment and a side information segment, or rate parameter recovery according to one or more aspects.

FIG. 4 is a block diagram of an example protocol stack that supports packet inspection using a MAC layer for a semantic encoding process according to one or more aspects.

FIG. 5 is a block diagram illustrating example processing operations that support packet inspection using a MAC layer for a semantic encoding process according to one or more aspects.

FIG. 6 is a block diagram illustrating example processing operations that support packet inspection using a MAC layer for a semantic encoding process according to one or more aspects.

FIG. 7 is a block diagram illustrating example processing operations that support packet inspection using a MAC layer for a semantic encoding process according to one or more aspects.

FIG. 8 is a block diagram illustrating example processing operations that support packet inspection using a MAC layer for a semantic encoding process according to one or more aspects.

FIG. 9 is a block diagram of an example encoder device that supports associating a data segment and a side information segment according to one or more aspects.

FIG. 10 is a block diagram of an example packet that supports associating a data segment and a side information segment according to one or more aspects.

FIG. 11 is a block diagram of another example packet that supports associating a data segment and a side information segment according to one or more aspects.

FIG. 12 is a block diagram of an example segmentation operation that supports associating a data segment and a side information segment according to one or more aspects.

FIG. 13 is a block diagram of another example segmentation operation that supports associating a data segment and a side information segment according to one or more aspects.

FIG. 14 is a block diagram of an example encoding process that supports rate parameter recovery according to one or more aspects.

FIG. 15 is a block diagram of an example decoding process that supports rate parameter recovery according to one or more aspects.

FIG. 16 is a flow diagram illustrating an example process that supports packet inspection using a MAC layer for a semantic encoding process according to one or more aspects.

FIG. 17 is a flow diagram illustrating an example process that supports packet inspection using a MAC layer for a semantic encoding process according to one or more aspects.

FIG. 18 is a flow diagram illustrating an example process that supports packet inspection using a MAC layer for a semantic encoding process according to one or more aspects.

FIG. 19 is a flow diagram illustrating an example process that supports packet inspection using a MAC layer for a semantic encoding process according to one or more aspects.

FIG. 20 is a flow diagram illustrating an example process that supports associating a data segment and a side information segment according to one or more aspects.

FIG. 21 is a flow diagram illustrating an example process that supports associating a data segment and a side information segment according to one or more aspects.

FIG. 22 is a flow diagram illustrating an example process that supports rate parameter recovery according to one or more aspects.

FIG. 23 is a flow diagram illustrating an example process that supports rate parameter recovery according to one or more aspects.

FIG. 24 is a block diagram of an example UE that supports one or more of packet inspection using a MAC layer for a semantic encoding process, associating a data segment and a side information segment, or rate parameter recovery according to one or more aspects.

FIG. 25 is a block diagram of an example base station that supports one or more of packet inspection using a MAC layer for a semantic encoding process, associating a data segment and a side information segment, or rate parameter recovery according to one or more aspects.

Like reference numbers and designations in the various drawings indicate like elements.

### DETAILED DESCRIPTION

Various aspects of the disclosure are described more fully hereinafter with reference to the accompanying drawings. This disclosure may, however, be embodied in many different forms and are not to be construed as limited to any specific structure or function presented throughout this disclosure. Rather, these aspects are provided so that this disclosure will be thorough and complete, and will fully convey the scope of the disclosure to those skilled in the art. Based on the teachings herein one skilled in the art may appreciate that the scope of the disclosure is intended to cover any aspect of the disclosure disclosed herein, whether implemented independently of or combined with any other aspect of the disclosure. For example, an apparatus may be implemented or a method may be practiced using any quantity of the aspects set forth herein. In addition, the scope of the disclosure is intended to cover such an apparatus or method which is practiced using other structure, functionality, or structure and functionality in addition to or other than the various aspects of the disclosure set forth herein. Any aspect of the disclosure disclosed herein may be embodied by one or more elements of a claim.

Various aspects of the present disclosure relate to techniques that enable simplified encoding operations, decoding operations, or both, by a wireless communication device, such as a user equipment (UE) or a base station. In a first example, the wireless communication device may use a packet data convergence protocol (PDCP) layer to insert flags within packets (such as within PDCP headers of the packets) to indicate encoding processes associated with the packets. The wireless communication device may use a medium access control layer (MAC) to inspect the packets. If two inspected packets indicate different respective encoding processes, including at least one semantic encoding process, the MAC layer may avoid assigning the packets to the same MAC packet data unit (PDU) (also referred to as multiplexing the packets) and may instead assign the packets to different respective MAC PDUs. In an alternative implementation of the first example, packets associated with different encoding processes may be assigned to different radio bearers (instead of indicating the different encoding processes using flags), and the MAC layer may avoid assigning the packets to the same MAC PDU in accordance with the packets being associated with the different radio bearers.

Alternatively, or in addition, in a second example, the wireless communication device may link a data segment and a side information segment associated with the data segment. To illustrate, some semantic encoding processes may generate side information indicating a compressed version of a feature probability associated with data, such as with image data. Prior to transmitting the data and the side information, a wireless communication protocol may specify that the data and the side information is to be segmented, such as using a radio link control (RLC) layer associated with the wireless communication device. In some aspects, the wireless communication device may generate an indication that a data segment is associated with a side information segment. As a result, a physical (PHY) layer that receives such segments may perform joint channel and source (JSCC) encoding of a data segment using the correct respective side information segment based on the indication. In some implementations of the second example, the indication may include a segment offset value indicating a position of the data segment relative to the side information segment within a packet. In some other implementations of the second example, the data segment and the side information segment may be included in different packets, and the indication may include a common value (such as a serial number) that links the data segment and the side information segment.

Alternatively, or in addition, in a third example, the wireless communication device may receive data including multiple data packets each associated with a respective rate parameter (also referred to herein as a length or size). The data packets may be received via an analog transmission. The wireless communication device may recover such rate parameters without an explicit identification of the rate parameters. To illustrate, in one implementation of the third example, the wireless communication device may receive rate recovery information including a channel usage parameter and index values to a lookup table. The wireless communication device may identify the rate parameters from the lookup table using the index values and may determine a total channel usage (such as a total number of resources) associated with the data packets using the channel usage parameter and a sum of the rate parameters. In another implementation of the third example, the wireless communication device may use side information to determine the rate parameters without using a lookup table. Further, such an implementation may be performed with or without receiving a configuration of a total transport block (TB) size associated with the data.

Particular implementations of the subject matter described in this disclosure can be implemented to realize one or more of the following potential advantages. In some aspects, by avoiding multiplexing packets associated with different encoding processes into the same packet, a wireless communication device may ensure that such a packet includes data of at most one semantic encoding process, which may improve certain operations that utilize a content type of the data, such as a JSCC encoding operation that utilizes the content type for encoding efficiency. Alternatively, or in addition, by indicating that a data segment is associated with a side information segment, the wireless communication device may encode a data segment based on the correct side information segment, which may avoid a mismatch between non-corresponding segments. Alternatively, or in addition, by using rate recovery information to indicate and recover rate parameters associated with data packets, wireless devices may avoid transmitting and receiving an explicit indication of the rate parameters, which may be relatively large, thus reducing an amount of signaling and wireless resources used in a wireless communication system.

In various implementations, the techniques and apparatus may be used for wireless communication networks such as code division multiple access (CDMA) networks, time division multiple access (TDMA) networks, frequency division multiple access (FDMA) networks, orthogonal FDMA (OFDMA) networks, single-carrier FDMA (SC-FDMA) networks, LTE networks, GSM networks, 5th Generation (5G) or new radio (NR) networks (sometimes referred to as “5G NR” networks, systems, or devices), as well as other communications networks. As described herein, the terms “networks” and “systems” may be used interchangeably. In some implementations, two or more wireless communications systems, also referred to as wireless communications networks, may be configured to provide or participate in authorized shared access between the two or more wireless communications systems.

A CDMA network may implement a radio technology such as universal terrestrial radio access (UTRA), cdma2000, and the like. UTRA includes wideband-CDMA (W-CDMA) and low chip rate (LCR). CDMA2000 covers IS-2000, IS-95, and IS-856 standards.

A TDMA network may implement a radio technology such as Global System for Mobile Communications (GSM). 3GPP defines standards for the GSM EDGE (enhanced data rates for GSM evolution) radio access network (RAN), also denoted as GERAN. GERAN is the radio component of GSM or GSM EDGE, together with the network that joins the base stations (for example, the Ater and Abis interfaces, among other examples) and the base station controllers (for example, A interfaces, among other examples). The radio access network represents a component of a GSM network, through which phone calls and packet data are routed from and to the public switched telephone network (PSTN) and Internet to and from subscriber handsets, also known as user terminals or user equipments (UEs). A mobile phone operator's network may include one or more GERANs, which may be coupled with UTRANs in the case of a UMTS or GSM network. Additionally, an operator network may include one or more LTE networks, or one or more other networks. The various different network types may use different radio access technologies (RATs) and radio access networks (RANs).

An OFDMA network may implement a radio technology such as evolved UTRA (E-UTRA), IEEE 802.11, IEEE 802.16, IEEE 802.20, flash-OFDM and the like. UTRA, E-UTRA, and GSM are part of universal mobile telecommunication system (UMTS). In particular, long term evolution (LTE) is a release of UMTS that uses E-UTRA. UTRA, E-UTRA, GSM, UMTS and LTE are described in documents provided from an organization named the “3rd Generation Partnership Project” (3GPP), and cdma2000 is described in documents from an organization named “3rd Generation Partnership Project 2” (3GPP2). These various radio technologies and standards are known or are being developed. For example, the 3GPP is a collaboration between groups of telecommunications associations that aims to define a globally applicable third generation (3G) mobile phone specification. 3GPP long term evolution (LTE) is a 3GPP project aimed at improving the universal mobile telecommunications system (UMTS) mobile phone standard. The 3GPP may define specifications for the next generation of mobile networks, mobile systems, and mobile devices. The present disclosure may describe certain aspects with reference to LTE, 4G, 5G, or NR technologies; however, the description is not intended to be limited to a specific technology or application, and one or more aspects described with reference to one technology may be understood to be applicable to another technology. Indeed, one or more aspects the present disclosure are related to shared access to wireless spectrum between networks using different radio access technologies or radio air interfaces.

5G networks contemplate diverse deployments, diverse spectrum, and diverse services and devices that may be implemented using an OFDM-based unified, air interface. To achieve these goals, further enhancements to LTE and LTE-A are considered in addition to development of the new radio technology for 5G NR networks. The 5G NR will be capable of scaling to provide coverage (1) to a massive Internet of things (IoTs) with an ultra-high density (such as ~1M nodes per km\hat{ }2), ultra-low complexity (such as ~10s of bits per see), ultra-low energy (such as ~10+ years of battery life), and deep coverage with the capability to reach challenging locations; (2) including mission-critical control with strong security to safeguard sensitive personal, financial, or classified information, ultra-high reliability (such as ~99.99990% reliability), ultra-low latency (such as ~1 millisecond (ms)), and users with wide ranges of mobility or lack thereof; and (3) with enhanced mobile broadband including extreme high capacity (such as ~10 Tbps per km\hat{ }2), extreme data rates (such as multi-Gbps rate, 100+ Mbps user experienced rates), and deep awareness with advanced discovery and optimizations.

5G NR devices, networks, and systems may be implemented to use optimized OFDM-based waveform features. These features may include scalable numerology and transmission time intervals (TTIs); a common, flexible framework to efficiently multiplex services and features with a dynamic, low-latency time division duplex (TDD) or frequency division duplex (FDD) design; and advanced wireless technologies, such as massive multiple input, multiple output (MIMO), robust millimeter wave (mmWave) transmissions, advanced channel coding, and device-centric mobility. Scalability of the numerology in 5G NR, with scaling of subcarrier spacing, may efficiently address operating diverse services across diverse spectrum and diverse deployments. For example, in various outdoor and macro coverage deployments of less than 3 GHz FDD or TDD implementations, subcarrier spacing may occur with 15 kHz, for example over 1, 5, 10, 20 MHz, and the like bandwidth. For other various outdoor and small cell coverage deployments of TDD greater than 3 GHz, subcarrier spacing may occur with 30 kHz over 80 or 100 MHz bandwidth. For other various indoor wideband implementations, using a TDD over the unlicensed portion of the 5 GHz band, the subcarrier spacing may occur with 60 kHz over a 160 MHz bandwidth. Finally, for various deployments transmitting with mmWave components at a TDD of 28 GHz, subcarrier spacing may occur with 120 kHz over a 500 MHz bandwidth.

The scalable numerology of 5G NR facilitates scalable TTI for diverse latency and quality of service (QoS) requirements. For example, shorter TTI may be used for low latency and high reliability, while longer TTI may be used for higher spectral efficiency. The efficient multiplexing of long and short TTIs to allow transmissions to start on symbol boundaries. 5G NR also contemplates a self-contained integrated subframe design with uplink or downlink scheduling information, data, and acknowledgement in the same subframe. The self-contained integrated subframe supports communications in unlicensed or contention-based shared spectrum, adaptive uplink or downlink that may be flexibly configured on a per-cell basis to dynamically switch between uplink and downlink to meet the current traffic needs.

For clarity, certain aspects of the apparatus and techniques may be described below with reference to example 5G NR implementations or in a 5G-centric way, and 5G terminology may be used as illustrative examples in portions of the description below; however, the description is not intended to be limited to 5G applications.

Moreover, it should be understood that, in operation, wireless communication networks adapted according to the concepts herein may operate with any combination of licensed or unlicensed spectrum depending on loading and availability. Accordingly, it will be apparent to a person having ordinary skill in the art that the systems, apparatus and methods described herein may be applied to other communications systems and applications than the particular examples provided.

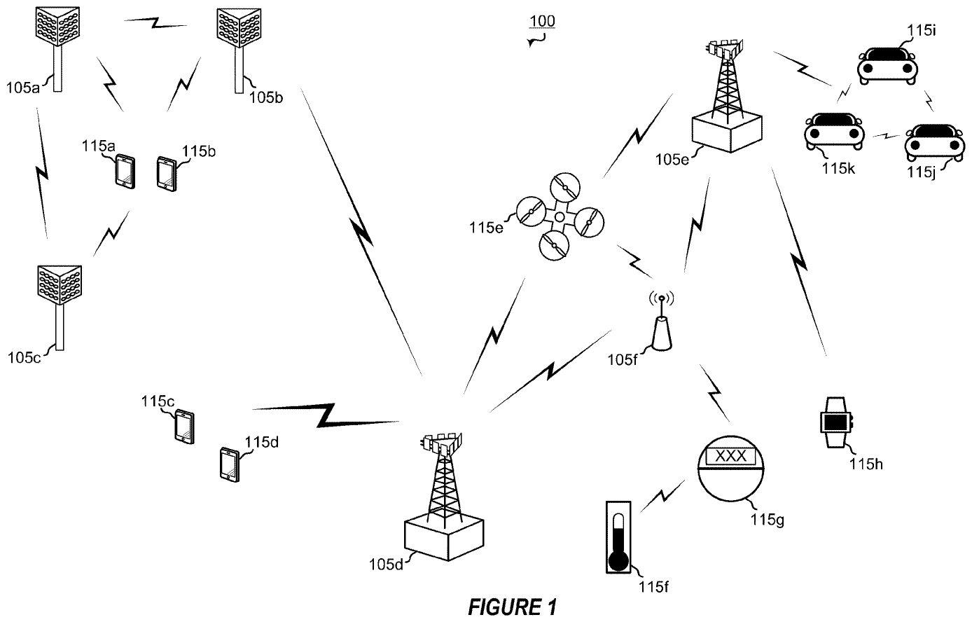

FIG. 1 is a block diagram illustrating details of an example wireless communication system. The wireless communication system may include wireless network 100. The wireless network 100 may, for example, include a 5G wireless network. As appreciated by those skilled in the art, components appearing in FIG. 1 are likely to have related counterparts in other network arrangements including, for example, cellular-style network arrangements and non-cellular-style-network arrangements, such as device-to-device, peer-to-peer or ad hoc network arrangements, among other examples.

The wireless network 100 illustrated in FIG. 1 includes a number of base stations 105 and other network entities. A base station may be a station that communicates with the UEs and may be referred to as an evolved node B (eNB), a next generation eNB (gNB), an access point, and the like. Each base station 105 may provide communication coverage for a particular geographic area. In 3GPP, the term “cell” can refer to this particular geographic coverage area of a base station or a base station subsystem serving the coverage area, depending on the context in which the term is used. In implementations of the wireless network 100 herein, the base stations 105 may be associated with a same operator or different operators, such as the wireless network 100 may include a plurality of operator wireless networks. Additionally, in implementations of the wireless network 100 herein, the base stations 105 may provide wireless communications using one or more of the same frequencies, such as one or more frequency bands in licensed spectrum, unlicensed spectrum, or a combination thereof, as a neighboring cell. In some examples, an individual base station 105 or UE 115 may be operated by more than one network operating entity. In some other examples, each base station 105 and UE 115 may be operated by a single network operating entity.

A base station may provide communication coverage for a macro cell or a small cell, such as a pico cell or a femto cell, or other types of cell. A macro cell generally covers a relatively large geographic area, such as several kilometers in radius, and may allow unrestricted access by UEs with service subscriptions with the network provider. A small cell, such as a pico cell, would generally cover a relatively smaller geographic area and may allow unrestricted access by UEs with service subscriptions with the network provider. A small cell, such as a femto cell, would also generally cover a relatively small geographic area, such as a home, and, in addition to unrestricted access, may provide restricted access by UEs having an association with the femto cell, such as UEs in a closed subscriber group (CSG), UEs for users in the home, and the like. A base station for a macro cell may be referred to as a macro base station. A base station for a small cell may be referred to as a small cell base station, a pico base station, a femto base station or a home base station. In the example shown in FIG. 1, base stations 105d and 105e are regular macro base stations, while base stations 105a-105c are macro base stations enabled with one of 3 dimension (3D), full dimension (FD), or massive MIMO. Base stations 105a-105c take advantage of their higher dimension MIMO capabilities to exploit 3D beamforming in both elevation and azimuth beamforming to increase coverage and capacity. Base station 105f is a small cell base station which may be a home node or portable access point. A base station may support one or multiple cells, such as two cells, three cells, four cells, and the like.

The wireless network 100 may support synchronous or asynchronous operation. For synchronous operation, the base stations may have similar frame timing, and transmissions from different base stations may be approximately aligned in time. For asynchronous operation, the base stations may have different frame timing, and transmissions from different base stations may not be aligned in time. In some scenarios, networks may be enabled or configured to handle dynamic switching between synchronous or asynchronous operations.

The UEs 115 are dispersed throughout the wireless network 100, and each UE may be stationary or mobile. It should be appreciated that, although a mobile apparatus is commonly referred to as user equipment (UE) in standards and specifications promulgated by the 3GPP, such apparatus may additionally or otherwise be referred to by those skilled in the art as a mobile station (MS), a subscriber station, a mobile unit, a subscriber unit, a wireless unit, a remote unit, a mobile device, a wireless device, a wireless communications device, a remote device, a mobile subscriber station, an access terminal (AT), a mobile terminal, a wireless terminal, a remote terminal, a handset, a terminal, a user agent, a mobile client, a client, or some other suitable terminology. Within the present document, a “mobile” apparatus or UE need not necessarily have a capability to move, and may be stationary. Some non-limiting examples of a mobile apparatus, such as may include implementations of one or more of the UEs 115, include a mobile, a cellular (cell) phone, a smart phone, a session initiation protocol (SIP) phone, a wireless local loop (WLL) station, a laptop, a personal computer (PC), a notebook, a netbook, a smart book, a tablet, and a personal digital assistant (PDA). A mobile apparatus may additionally be an “Internet of things” (IoT) or “Internet of everything” (IoE) device such as an automotive or other transportation vehicle, a satellite radio, a global positioning system (GPS) device, a global navigation satellite system (GNSS) device, a logistics controller, a drone, a multi-copter, a quad-copter, a smart energy or security device, a solar panel or solar array, municipal lighting, water, or other infrastructure; industrial automation and enterprise devices; consumer and wearable devices, such as eyewear, a wearable camera, a smart watch, a health or fitness tracker, a mammal implantable device, a gesture tracking device, a medical device, a digital audio player (such as MP3 player), a camera or a game console, among other examples; and digital home or smart home devices such as a home audio, video, and multimedia device, an appliance, a sensor, a vending machine, intelligent lighting, a home security system, or a smart meter, among other examples. In one aspect, a UE may be a device that includes a Universal Integrated Circuit Card (UICC). In another aspect, a UE may be a device that does not include a UICC. In some aspects, UEs that do not include UICCs may be referred to as IoE devices. The UEs 115a-115d of the implementation illustrated in FIG. 1 are examples of mobile smart phone-type devices accessing the wireless network 100. A UE may be a machine specifically configured for connected communication, including machine type communication (MTC), enhanced MTC (eMTC), narrowband IoT (NB-IoT) and the like. The UEs 115e-115k illustrated in FIG. 1 are examples of various machines configured for communication that access 5G network 100.

A mobile apparatus, such as the UEs 115, may be able to communicate with any type of the base stations, whether macro base stations, pico base stations, femto base stations, relays, and the like. In FIG. 1, a communication link (represented as a lightning bolt) indicates wireless transmissions between a UE and a serving base station, which is a base station designated to serve the UE on the downlink or uplink, or desired transmission between base stations, and backhaul transmissions between base stations. Backhaul communication between base stations of the wireless network 100 may occur using wired or wireless communication links.

In operation at the 5G network 100, the base stations 105a-105c serve the UEs 115a and 115b using 3D beamforming and coordinated spatial techniques, such as coordinated multipoint (CoMP) or multi-connectivity. Macro base station 105d performs backhaul communications with the base stations 105a-105c, as well as small cell, the base station 105f. Macro base station 105d also transmits multicast services which are subscribed to and received by the UEs 115c and 115d. Such multicast services may include mobile television or stream video, or may include other services for providing community information, such as weather emergencies or alerts, such as Amber alerts or gray alerts.

The wireless network 100 of implementations supports mission critical communications with ultra-reliable and redundant links for mission critical devices, such the UE 115e, which is a drone. Redundant communication links with the UE 115e include from the macro base stations 105d and 105e, as well as small cell base station 105f Other machine type devices, such as UE 115f (thermometer), the UE 115g (smart meter), and the UE 115h (wearable device) may communicate through the wireless network 100 either directly with base stations, such as the small cell base station 105f, and the macro base station 105e, or in multi-hop configurations by communicating with another user device which relays its information to the network, such as the UE 115f communicating temperature measurement information to the smart meter, the UE 115g, which is then reported to the network through the small cell base station 105f. The 5G network 100 may provide additional network efficiency through dynamic, low-latency TDD or FDD communications, such as in a vehicle-to-vehicle (V2V) mesh network between the UEs 115i-115k communicating with the macro base station 105e.

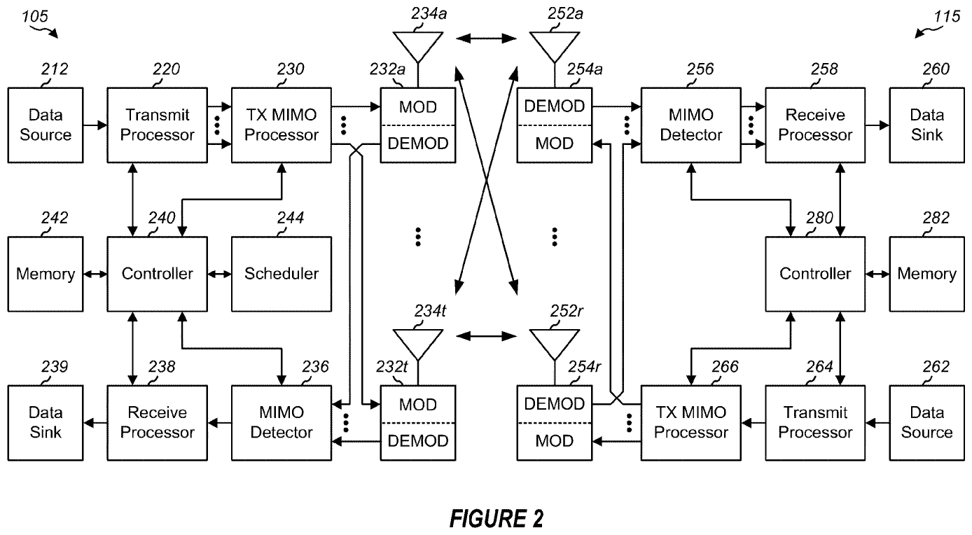

FIG. 2 is a block diagram conceptually illustrating an example design of a base station 105 and a UE 115. The base station 105 and the UE 115 may be one of the base stations and one of the UEs in FIG. 1. For a restricted association scenario (as mentioned above), the base station 105 may be the small cell base station 105f in FIG. 1, and the UE 115 may be the UE 115c or 115d operating in a service area of the base station 105f, which in order to access the small cell base station 105f, would be included in a list of accessible UEs for the small cell base station 105f. Additionally, the base station 105 may be a base station of some other type. As shown in FIG. 2, the base station 105 may be equipped with antennas 234a through 234t, and the UE 115 may be equipped with antennas 252a through 252r for facilitating wireless communications.

At the base station 105, a transmit processor 220 may receive data from a data source 212 and control information from a controller 240. The control information may be for the physical broadcast channel (PBCH), physical control format indicator channel (PCFICH), physical hybrid-ARQ (automatic repeat request) indicator channel (PHICH), physical downlink control channel (PDCCH), enhanced physical downlink control channel (EPDCCH), or MTC physical downlink control channel (MPDCCH), among other examples. The data may be for the PDSCH, among other examples. The transmit processor 220 may process, such as encode and symbol map, the data and control information to obtain data symbols and control symbols, respectively. Additionally, the transmit processor 220 may generate reference symbols, such as for the primary synchronization signal (PSS) and secondary synchronization signal (SSS), and cell-specific reference signal. Transmit (TX) multiple-input multiple-output (MIMO) processor 230 may perform spatial processing on the data symbols, the control symbols, or the reference symbols, if applicable, and may provide output symbol streams to modulators (MODs) 232a through 232t. For example, spatial processing performed on the data symbols, the control symbols, or the reference symbols may include precoding. Each modulator 232 may process a respective output symbol stream, such as for OFDM, among other examples, to obtain an output sample stream. Each modulator 232 may additionally or alternatively process the output sample stream to obtain a downlink signal. For example, to process the output sample stream, each modulator 232 may convert to analog, amplify, filter, and upconvert the output sample stream to obtain the downlink signal. Downlink signals from modulators 232a through 232t may be transmitted via the antennas 234a through 234t, respectively.

At the UE 115, the antennas 252a through 252r may receive the downlink signals from the base station 105 and may provide received signals to the demodulators (DEMODs) 254a through 254r, respectively. Each demodulator 254 may condition a respective received signal to obtain input samples. For example, to condition the respective received signal, each demodulator 254 may filter, amplify, downconvert, and digitize the respective received signal to obtain the input samples. Each demodulator 254 may further process the input samples, such as for OFDM, among other examples, to obtain received symbols. MIMO detector 256 may obtain received symbols from demodulators 254a through 254r, perform MIMO detection on the received symbols if applicable, and provide detected symbols. Receive processor 258 may process the detected symbols, provide decoded data for the UE 115 to a data sink 260, and provide decoded control information to a controller 280. For example, to process the detected symbols, the receive processor 258 may demodulate, deinterleave, and decode the detected symbols.

On the uplink, at the UE 115, a transmit processor 264 may receive and process data (such as for the physical uplink shared channel (PUSCH)) from a data source 262 and control information (such as for the physical uplink control channel (PUCCH)) from the controller 280. Additionally, the transmit processor 264 may generate reference symbols for a reference signal. The symbols from the transmit processor 264 may be precoded by TX MIMO processor 266 if applicable, further processed by the modulators 254a through 254r (such as for SC-FDM, among other examples), and transmitted to the base station 105. At base station 105, the uplink signals from the UE 115 may be received by antennas 234, processed by demodulators 232, detected by MIMO detector 236 if applicable, and further processed by receive processor 238 to obtain decoded data and control information sent by the UE 115. The receive processor 238 may provide the decoded data to data sink 239 and the decoded control information to the controller 240.

The controllers 240 and 280 may direct the operation at the base station 105 and the UE 115, respectively. The controller 240 or other processors and modules at the base station 105 or the controller 280 or other processors and modules at the UE 115 may initiate, perform, or control one or more operations described herein. The memories 242 and 282 may store data and program codes for the base station 105 and The UE 115, respectively. Scheduler 244 may schedule UEs for data transmission on the downlink or uplink.

In some cases, the UE 115 and the base station 105 may operate in a shared radio frequency spectrum band, which may include licensed or unlicensed, such as contention-based, frequency spectrum. In an unlicensed frequency portion of the shared radio frequency spectrum band, the UEs 115 or the base stations 105 may traditionally perform a medium-sensing procedure to contend for access to the frequency spectrum. For example, the UE 115 or base station 105 may perform a listen-before-talk or listen-before-transmitting (LBT) procedure such as a clear channel assessment (CCA) prior to communicating in order to determine whether the shared channel is available. A CCA may include an energy detection procedure to determine whether there are any other active transmissions. For example, a device may infer that a change in a received signal strength indicator (RSSI) of a power meter indicates that a channel is occupied. Specifically, signal power that is concentrated in a certain bandwidth and exceeds a predetermined noise floor may indicate another wireless transmitter. In some implementations, a CCA may include detection of specific sequences that indicate use of the channel. For example, another device may transmit a specific preamble prior to transmitting a data sequence. In some cases, an LBT procedure may include a wireless node adjusting its own back off window based on the amount of energy detected on a channel or the acknowledge or negative-acknowledge (ACK or NACK) feedback for its own transmitted packets as a proxy for collisions.

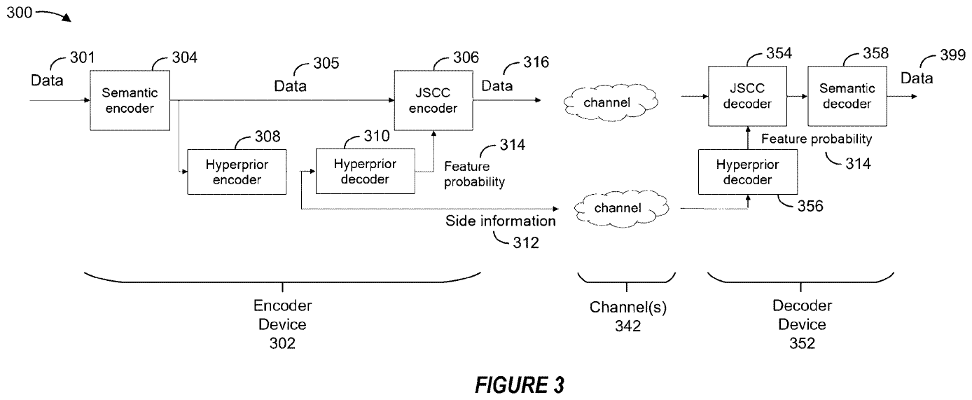

FIG. 3 is a block diagram of an example semantic encoding and decoding system 300 that supports packet inspection using a MAC layer for a semantic encoding process according to one or more aspects. The semantic encoding and decoding system 300 may include an encoder device 302 and a decoder device 352. In some examples, one or more of the base station 105 or the UE 115 may include one or more of the encoder device 302 or the decoder device 352.

The encoder device 302 may include a semantic encoder 304, a joint source and channel (JSCC) encoder 306, a hyperprior encoder 308, and a hyperprior decoder 310. The semantic encoder 304 may be coupled to the JSCC encoder 306 and to the hyperprior encoder 308. The hyperprior encoder 308 may be coupled to the hyperprior decoder 310. The hyperprior decoder 310 may be coupled to the JSCC encoder 306.

The decoder device 352 may include a JSCC decoder 354, a hyperprior decoder 356, and a semantic decoder 358. The JSCC decoder 354 may be coupled to the hyperprior decoder 356 and to the semantic decoder 358.

During operation, the semantic encoder 304 may receive data 301 and may semantically encode the data 301 to generate semantically encoded data, such as data 305. The hyperprior encoder 308 may receive the data 305 and may generate side information 312 in accordance with the data 305. The hyperprior decoder 310 may receive the side information 312 and may generate a feature probability 314 in accordance with the side information 312. In some examples, the side information 312 includes or corresponds to a compressed version of the feature probability 314. The JSCC encoder 306 may receive the data 305 from the semantic encoder 304 and may receive the feature probability 314 from the hyperprior decoder 310. The JSCC encoder 306 may perform JSCC encoding of the data 305 in accordance with the feature probability 314 to generate data 316.

The encoder device 302 (or another device) may transmit the data 316 and the side information 312 via the one or more channels 342. One or more devices may receive the data 316 and the side information 312. For example, the decoder device 352 may receive the data 316 and the side information 312. The decoder device 352 may input the data 316 to the JSCC decoder 354 and may input the side information 312 to the hyperprior decoder 356. The JSCC decoder 354 may decode the data 316 in accordance with the side information 312 to generate JSCC-decoded data. The semantic decoder 358 may receive the JSCC-decoded data and may semantically decode the JSCC-decoded data to generate data 399. In some examples, the data 399 may correspond to the data 301 input to the semantic encoder 304.

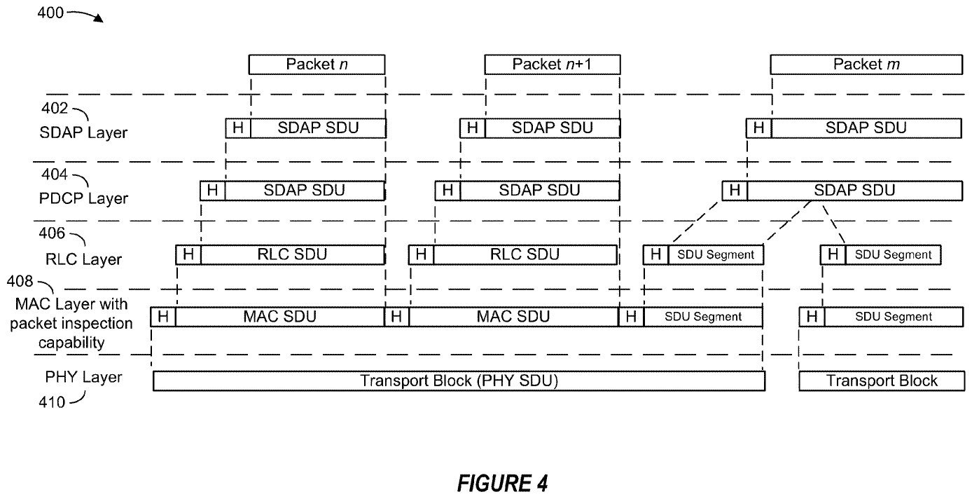

FIG. 4 is a block diagram of an example protocol stack 400 that supports packet inspection using a MAC layer for a semantic encoding process according to one or more aspects. In some examples, the encoder device 302 of FIG. 3 may operate in accordance with the protocol stack 400.

The protocol stack 400 may include a service data adaption protocol (SDAP) layer 402, a packet data convergence protocol (PDCP) layer 404, a radio link control (RLC) layer 406, a medium access control (MAC) layer 408, and a physical (PHY) layer 410.

During operation, the SDAP layer 402 may receive packets (such as packets n, n+1, and m) and may generate SDAP service data units (SDUs) in accordance with the packets. Each such SDAP SDU may be associated with a radio bearer. The PDCP layer 404 may generate PDCP SDUs in accordance with the SDAP SDUs. The RLC layer 406 may generate RLC SDUs in accordance with the PDCP SDUs. The MAC layer 408 may generate MAC SDUs in accordance with the RLC SDUs. The PHY layer 410 may generate transport blocks (TBs) (also referred to as PHY SDUs) in accordance with the MAC SDUs. In some examples, the data 316 of FIG. 3 may include the TBs of FIG. 4.

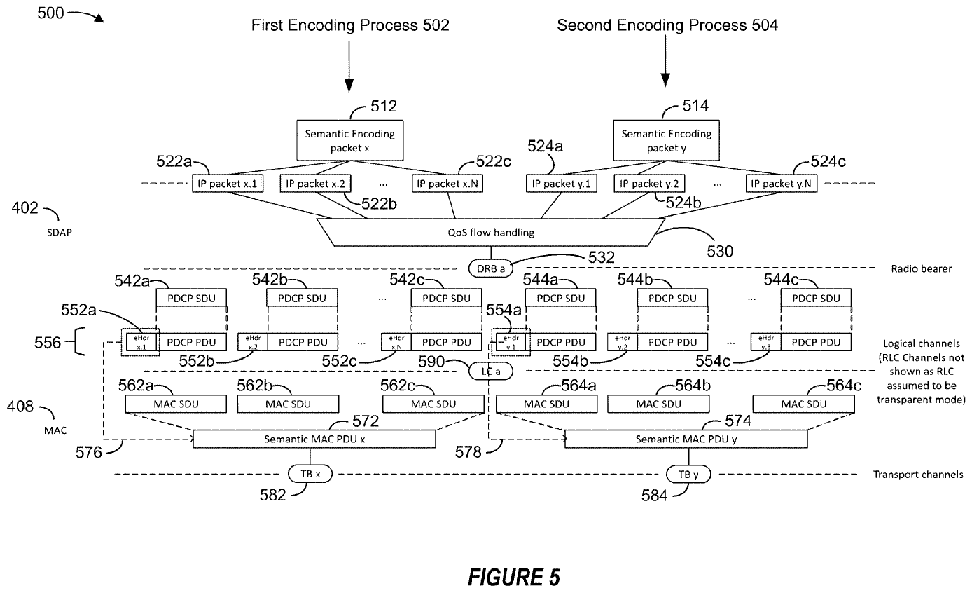

SDUs illustrated in FIG. 4 may include headers (indicated as “H”). SDUs generated based on packets n and n+1 may be associated with a first radio bearer, and SDUs generated based on packet m may be associated with a second radio bearer. In some examples, one or more packets may be segmented into segments. Further, In some aspects, the MAC layer 408 of FIG. 4 may have a packet inspection capability, such as described further with reference to FIGS. 5-8.

FIG. 5 is a block diagram illustrating example processing operations 500 that support packet inspection using a MAC layer for a semantic encoding process according to one or more aspects. In some examples, the processing operations 500 may be performed using at least the SDAP layer 402, the PDCP layer 404, and the MAC layer 408.

The processing operations 500 may include generating a first semantic encoding packet via a vi and may further include generating a second semantically encoded packet 514 via a second encoding process 504. In the example of FIG. 4, the first encoding process 502 and the second encoding process 504 are both semantic encoding processes. For example, the semantic encoder 304 of FIG. 3 may semantically encode one group of data via the first encoding process 502 to generate the first semantically encoded packet 512 and may semantically encode another group of data via the second encoding process 504 to generate the second semantically encoded packet 514.

The processing operations 500 may further include generating packets based on the semantically encoded packets 512, 514, such as by generating packets 522a, 522b, and 522c based on the first semantically encoded packet 512 and by generating packets 524a, 524b, and 524c based on the second semantically encoded packet 514. In some examples, the packets 522a-c and 524a-c may include Internet Protocol (IP) packets having an IP format.

The processing operations 500 may further include performing QoS flow handling, at 530. The QoS flow handling may be associated with a first radio bearer 532, such as a data radio bearer (DRB).

The processing operations 500 may further include adding PDCP headers to PDCP SDUs to generate PDCP packet data units (PDUs) 556. For example, PDCP headers 552a, 552b, and 552c may be added to PDCP SDUs 542a, 542b, and 542c, respectively. As another example, PDCP headers 554a, 554b, and 554c may be added to PDCP SDUs 544a, 544b, and 544c, respectively.

Each of the PDCP headers 552a-c may include a first flag indicating the first encoding process 502. In the example of FIG. 5, the first flag may be represented as “x” in the PDCP headers 552a-c. Further, each of the PDCP headers 554a-c may include a second flag indicating the second encoding process 504. In the example of FIG. 5, the second flag may be represented as “y” in the PDCP headers 554a-c.

The processing operations 500 may further include generating one or more first packets that are associated with the first flag indicating the first encoding process 502. The one or more first packets may include MAC SDUs 562a, 562b, and 562c. The processing operations 500 may also include generating one or more second packets that are associated with the second flag indicating the second encoding process 504. The one or more second packets may include MAC SDUs 564a, 564b, and 564c.

The processing operations 500 may further include inspecting packets (or headers of packets) using the MAC layer 408 to generate a first MAC PDU 572 and a second MAC PDU 574. To illustrate, the MAC layer 408 may inspect the MAC SDUs 562a-c and 564a-c (such as by inspecting PDCP headers included in the MAC SDUs 562a-c and 564a-c) to identify the first flag and the second flag. By inspecting the PDCP headers, the MAC layer 408 may avoid multiplexing packets associated with different semantic encoding processes. In the example of FIG. 5, the first MAC PDU 572 may be a semantic MAC PDU that includes semantically encoded packets associated with the first encoding process 502, and the second MAC PDU 574 may be a semantic MAC PDU that includes semantically encoded packets associated with the second encoding process 504.

For example, the MAC SDU 562a may include the PDCP header 552a. The MAC layer 408 may inspect, at operation 576, the PDCP header 552a to identify the first flag (“x”). In accordance with identifying the first flag, the MAC layer 408 may determine that the MAC SDU 562a is associated with the first encoding process 502. As another example, the MAC SDU 564a may include the PDCP header 554a. The MAC layer 408 may inspect, at operation 578, the PDCP header 554a to identify the second flag (“y”). In accordance with identifying the second flag, the MAC layer 408 may determine that the MAC SDU 564a is associated with the second encoding process 504.

In accordance with identifying the first flag and the second flag, the MAC layer 408 may avoid multiplexing any of the MAC SDUs 562a-c with any of the MAC SDUs 564a-c. For example, the MAC layer 408 may assign the MAC SDUs 562a-c to the first MAC PDU 572 and may assign the MAC SDUs 564a-c to the second MAC PDU 574.

The processing operations 500 may further include generating, in accordance with inspecting the MAC SDUs 562a-c to identify the first flag, a first TB 582 that includes, in accordance with the first flag, the MAC SDUs 562a-c. The processing operations 500 may further include generating, in accordance with inspecting the MAC SDUs 564a-c to identify the second flag, a second TB 584 that includes, in accordance with the second flag, the MAC SDUs 564a-c.

In some implementations, flags indicated by headers of semantic packets may indicate an indexing of the semantic packets. To illustrate, the example of FIG. 5 illustrates that each first header may include both an indication of the first encoding process 502 (such as “x”) as well as an index value following the indication (such as 1, 2, and N, where N indicates an quantity of the semantic packets). Similarly, each second header may include both an indication of the second encoding process 504 (such as “y”) as well as an index value following the indication (such as 1, 2, and 3). In such examples, the MAC layer 408 may perform one or more operations in accordance with such an indexing of semantic packets. For example, the MAC layer 408 may order the MAC SDUs 562a-c within the first MAC PDU 572 in accordance with the indexing. Similarly, the MAC layer 408 may order the MAC SDUs 564a-c within the second MAC PDU 574 in accordance with the indexing.

In some examples, semantically encoded data may be associated with a semantic type flag indicating that the data is semantically encoded. Further, the semantic type flag may be associated with a dedicated radio bearer, such as the first radio bearer 532, that is associated with the semantic type flag. For example, the dedicated radio bearer may be reserved for data that is associated with the semantic type flag. To further illustrate, the MAC SDUs 562a-c may be associated with the semantic type flag, and the first TB 582 may be transmitted via the dedicated radio bearer associated with the semantic type flag. As another example, the MAC SDUs 564a-c may be associated with the semantic type flag, and the second TB 584 may be transmitted via the dedicated radio bearer associated with the semantic type flag.

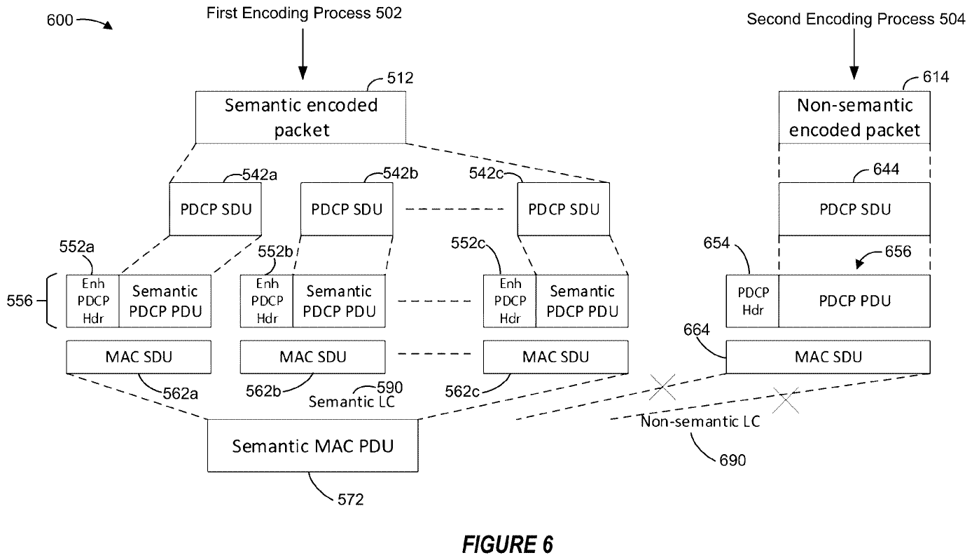

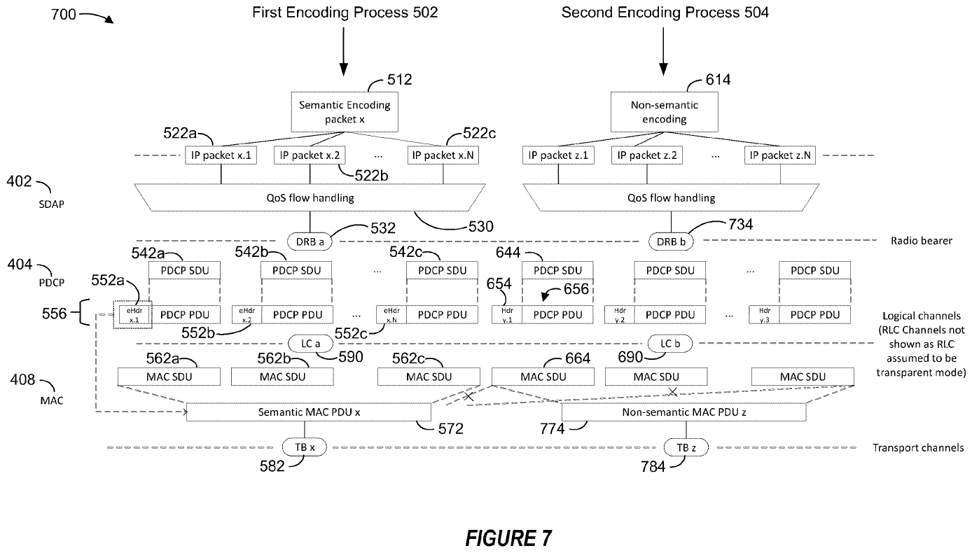

Alternatively or in addition to using a dedicated radio bearer associated with semantically encoded data, in some examples, a logical channel may be reserved for semantically encoded data. For example, a first logical channel (LC) 590 may be reserved for semantically encoded data, and both the first TB 582 and the second TB 584 may be associated with the first LC 590. Further, non-semantically encoded data may be associated with one or more additional logical channels other than the first LC 590, as described further with reference to certain examples of FIGS. 6 and 7.

FIG. 6 is a block diagram illustrating example processing operations 600 that support packet inspection using a MAC layer for a semantic encoding process according to one or more aspects. In some examples, the processing operations 600 may include one or more processing operations described with reference to FIG. 5, such as generating the first MAC PDU 572 in accordance with the first semantically encoded packet 512 associated with the first encoding process 502. The example of FIG. 6 also illustrates a non-semantically encoded packet 614 that may be generated in accordance with the second encoding process 504. In the example of FIG. 6, the second encoding process 504 may be a non-semantic encoding process.

The processing operations may include generating a PDCP SDU 644 in accordance with the non-semantically encoded packet 614, adding a PDCP header 654 to the PDCP SDU 644 to generate a PDCP PDU 656, and generating a MAC SDU 664 in accordance with the PDCP PDU 656. The PDCP PDU 656 may be associated with a second LC 690. In some examples, the second LC 690 may be associated with non-semantically encoded data, such as the MAC SDU 664.

FIG. 6 also illustrates an example in which non-semantically encoded data is not multiplexed with semantically-encoded data. For example, the MAC layer 408 of FIGS. 4 and 5 may avoid combining the MAC SDU 664 with semantically encoded MAC SDUs, such as by avoiding combining the MAC SDU 664 with the MAC SDUs 562a-c during generation of the first MAC PDU 572. In some examples, the MAC layer 408 of FIGS. 4 and 5 may avoid combining the MAC SDU 664 with such semantically encoded MAC SDUs in accordance with identifying that the MAC SDU 664 includes non-semantically encoded data, such as in accordance with failing to identify a semantic type flag within the MAC SDU 664. In some such examples, the MAC SDUs 562a-c may include the semantic type flag, and the MAC SDU 664 may exclude the semantic type flag.

FIG. 7 is a block diagram illustrating example processing operations 700 that support packet inspection using a MAC layer for a semantic encoding process according to one or more aspects. In some examples, the processing operations 700 may include one or more processing operations described with reference to FIGS. 5 and 6, such as generating the first MAC PDU 572 in accordance with the first semantically encoded packet 512 associated with the first encoding process 502, as described with reference to FIG. 5. The processing operations 700 may further include generating a second MAC PDU 774 in accordance with the non-semantically encoded packet 614 associated with the second encoding process 504. In the example of FIG. 7, the second encoding process 504 may be a non-semantic encoding process.

In some examples, one or more first packets may associated with a first logical channel that is reserved for semantically encoded data, and one or more second packets may be associated with a second logical channel that is reserved for non-semantically encoded data. To illustrate, the MAC SDUs 562a-c may be associated with the first LC 590, which may be reserved for semantically encoded data. The MAC SDU 664 may be associated with the second LC 690, which may be reserved for non-semantically encoded data, such as the non-semantically encoded packet 614.

Further, the MAC layer 408 may selectively assign packets to different MAC PDUs based on whether the packets include semantically encoded data or non-semantically encoded data. The determination may be based on whether the packets are associated with a logical channel reserved for semantically encoded data or a logical channel reserved for non-semantically encoded data. To illustrate, the MAC layer 408 may assign the one or more first packets to the first MAC PDU 572 in accordance with the one or more first packets being associated with the first LC 590 and may assign the one or more second packets to a second MAC PDU 774 (instead of the first MAC PDU 572) in accordance with the one or more second packets being associated with the second logical channel 690.

In some examples, different such logical channels may be associated with different respective logical channel groups (LCGs), such as where one LCG is associated with semantically encoded data, and where another LCG is associated with non-semantically encoded data. To illustrate, the first LC 590 may be associated with a first LCG associated with semantically encoded data, and the second LC 690 may be associated with non-semantically encoded data and that is not multiplexed with the first logical channel. In some implementations, the first encoding process 502 may be associated with the first radio bearer 532, and the second encoding process 504 may be associated with a second radio bearer 734.

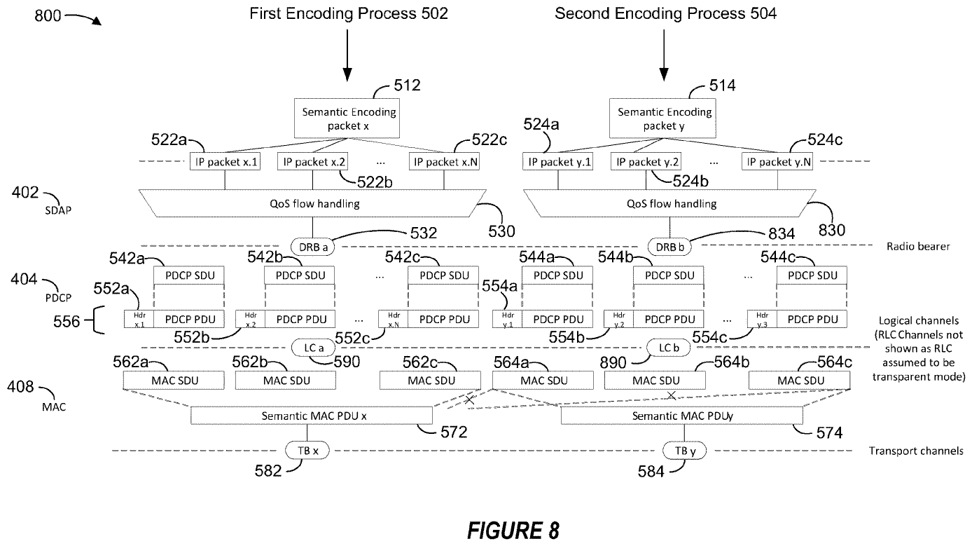

FIG. 8 is a block diagram illustrating example processing operations 800 that support packet inspection using a MAC layer for a semantic encoding process according to one or more aspects. In the example of FIG. 8, the second encoding process 504 may be a semantic encoding process. FIG. 8 also illustrates that the first encoding process 502 may be associated with the first logical channel 590 and that the second encoding process 504 may be associated with a second logical channel 890.

In FIG. 8, each different semantic encoding process may be associated with a different respective radio bearer. For example, the first encoding process 502 may be associated with the first radio bearer 532, and the second encoding process 504 may be associated with a second radio bearer 834. The MAC layer 408 may assign, in accordance with the first radio bearer 532 and the second radio bearer 834, one or more first packets and one or more second packets to different respective MAC PDUs. For example, the MAC layer 408 may assign one or more first packets (such as the MAC SDUs 562a-c) to the first MAC PDU 572 in accordance with the one or more first packets being associated with the first logical channel 590. As another example, the MAC layer 408 may assign one or more second packets (such as the MAC SDUs 564a-c) to the second MAC PDU 574 in accordance with the one or more second packets being associated with the second logical channel 890.

FIG. 8 also illustrates that the SDAP layer 402 may perform the QoS flow handling 530 associated with the first encoding process 502 and QoS flow handling 830 associated with the second encoding process 504. In some aspects, a wireless communication device (such as the UE 115 or the base station 105 of FIG. 2) may execute one or more applications to generate the first semantically encoded packet 512 and the second semantically encoded packet 514. Performing the QoS flow handling 530 may include generating first QoS data including a semantic type flag that indicates that the first encoding process 502 is a semantic encoding process. Further, performing the QoS flow handling 830 may include generating second QoS data including a semantic type flag that indicates whether the second encoding process 504 is a semantic or non-semantic encoding process.

The SDAP layer 402 may assign radio bearers to packets in accordance with the semantic type flags. For example, in accordance with the first QoS data including a semantic type flag that indicates that the first encoding process 502 is a semantic encoding process, the SDAP layer 402 may assign, to packets associated with the first encoding process 502, a radio bearer (such as the first radio bearer 532) reserved for semantic communications. As another example, in accordance with the second QoS data including a semantic type flag that indicates that the second encoding process 504 is a semantic or non-semantic encoding process, the SDAP layer 402 may assign, to packets associated with the second encoding process 504, a radio bearer (such as the second radio bearer 834) reserved for semantic or non-semantic communications, respectively.

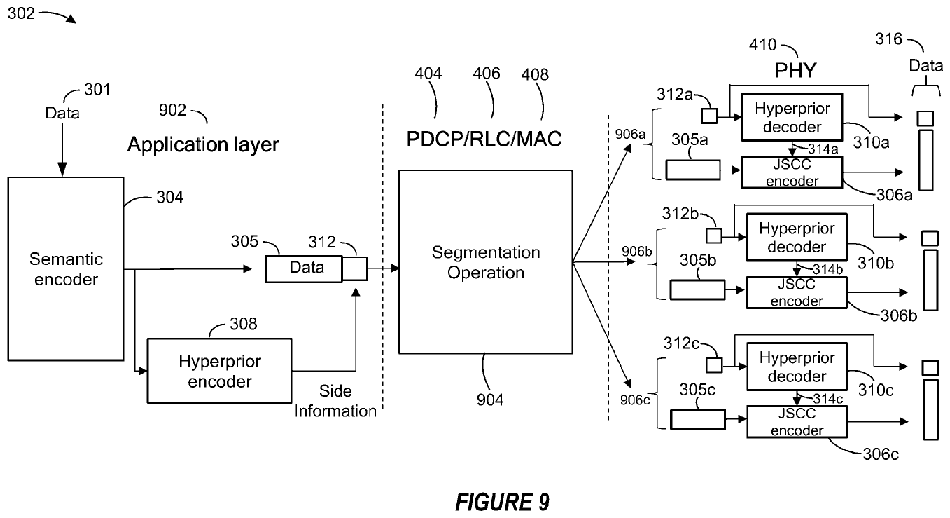

FIG. 9 is a block diagram of an example encoder device 302 that supports associating a data segment and a side information segment according to one or more aspects. The encoder device 302 may include one or more features described above, such as one or more features described with reference to FIGS. 3 and 4. For example, the encoder device 302 may include the semantic encoder 304 and the hyperprior encoder 308. The encoder device 302 may also components corresponding to the JSCC encoder 306 and the hyperprior decoder 310, such as JSCC encoders 306a, 306b, and 306c and hyperprior decoders 310a, 310b, and 310c. The encoder device 302 may perform one or more operations using the PDCP layer 404, the RLC layer 406, the MAC layer 408, and the PHY layer 410.

During operation, the encoder device 302 may semantically encode data (such as the data 301) to generate semantically encoded data, such as the data 305. The hyperprior encoder 308 may receive the data 305 and may generate the side information 312 in accordance with the data 305. The encoder device 302 may generate the data 305 and the side information using an application layer 902.

The encoder device 302 may perform a segmentation operation 904. In some examples, the encoder device 302 may perform the segmentation operation using one or more of the PDCP layer 404, the RLC layer 406, or the MAC layer 408. In some examples, the encoder device 302 may perform the segmentation operation 904 in accordance with one or more criteria, such as a one or more of modulation and coding scheme (MCS) associated with the data 305 and the side information 312, a resource allocation associated with the data 305 and the side information 312, or one or more other criteria.

Performing the segmentation operation 904 may include segmenting the data 305 and the side information 312 into segments and generating packets that include the segments, such as packets 906a, 906b, and 906c. Although the example of FIG. 9 may illustrate three such packets, in other examples, the segmentation operation 904 may generate a different quantity of packets, such as two packets, four packets, or another number of packets. The packet 906a may include a data segment 305a and a side information segment 312a. The packet 906b may include a data segment 305b and a side information segment 312b, and the packet 906c may include a data segment 305c and a side information segment 312c. In some examples, the side information segments 312a, 312c, and 312c may each indicate a respective feature probability associated with the data segments 305a, 305b, and 305c.

After performance of the segmentation operation 904, the PHY layer 410 may receive segments via packets generated using the segmentation operation 904. For example, the PHY layer 410 may receive the data segment 305a and the side information segment 312a via the packet 906a. As additional examples, the PHY layer 410 may receive the data segment 305b and the side information segment 312b via the packet 906b and may receive the data segment 305c and the side information segment 312c via the packet 906c.

The hyperprior decoders 310a, 310b, and 310c may receive the side information segments 312a, 312b, and 312c, respectively, and may generate feature probabilities 314a, 314b, and 314c associated with the side information segments 312a, 312b, and 312c, respectively. The JSCC encoders 306a, 306b, and 306c may receive the data segments 305a, 305b, and 305c and the feature probabilities 314a, 314b, and 314c, respectively. The JSCC encoders 306a, 306b, and 306c may JSCC encode the data segments 305a, 305b, and 305c in accordance with the side information segments 312a, 312b, and 312c, respectively, and in accordance with the feature probabilities 314a, 314b, and 314c, respectively, to generate JSCC encoded data. The data 316 may include the JSCC encoded data and the side information 312a-c.

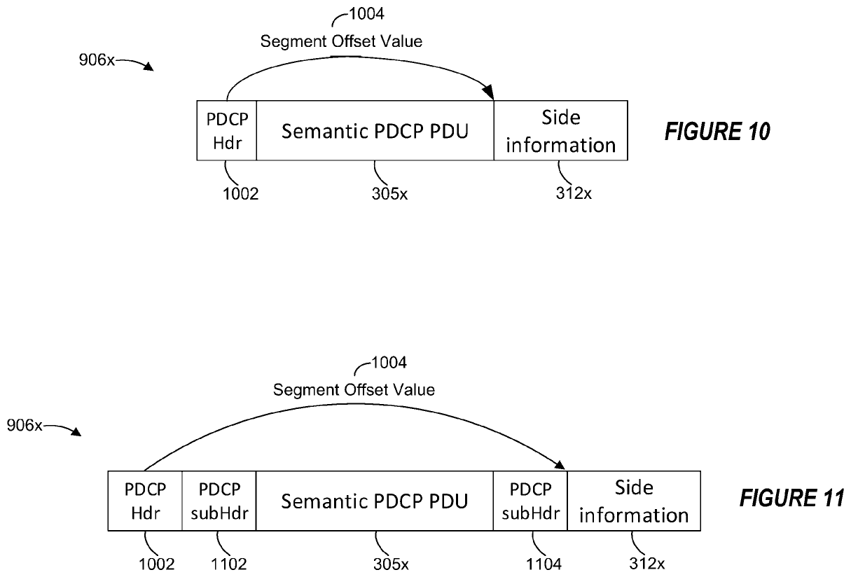

In some circumstances, the segmentation operation 904 may result in dissociation of data from side information associated with the data. For example, in some circumstances, after performance of the segmentation operation 904, the PHY layer 410 may be unable to determine which of the data segments 305a, 305b, and 305c is associated with which of the side information segments 312a, 312b, and 312c. In such circumstances, if the PHY layer 410 JSCC encodes a data segment based on the incorrect side information segment, poor performance may result. For example, JSCC encoding the data segment 305a based on the side information segment 312b or 312c may result in poor performance. In some aspects of the disclosure, the encoder device 302 may provide an indication that a data segment is associated with a side information segment, as described further with reference to FIGS. 10-13.

FIG. 10 is a block diagram of an example packet 906x that supports associating a data segment and a side information segment according to one or more aspects. The packet 906x may include a header 1002 (such as a PDCP header generated by the PDCP layer 404), a data segment 305x (such as a semantic PDCP PDU generated by the PDCP layer 404), and a side information segment 312x. In some examples, the packet 906x may correspond to one of the packets 906a-c of FIG. 9.

The packet 906x also may include an indication that the side information segment 312x is associated with the data segment 305x. For example, the indication may include or correspond to a segment offset value 1004x indicating a location of one or more of the data segment 305x or the side information segment 312x within the packet 906x. As an illustrative example, the segment offset value 1004x may indicate one or more of a beginning or end position (such as a bit or byte position) of the data segment 305x within the packet 906x or a beginning position or end position (such as a bit or byte position) of the side information segment 312x within the packet 906x. In some examples, the header 1002 may include the segment offset value 1004x, first information associated with the data segment 305x, and second information associated with the side information segment 312x.

FIG. 11 is a block diagram of another example packet 906x that supports associating a data segment and a side information segment according to one or more aspects. In the example of FIG. 11, the packet 906x includes a first sub-header 1102 associated with the data segment 305x and also includes a second sub-header 1104 associated with the side information segment 312x. In some examples, the sub-headers 1102, 1104 may correspond to PDCP sub-headers generated by the PDCP layer 404 of FIG. 4.

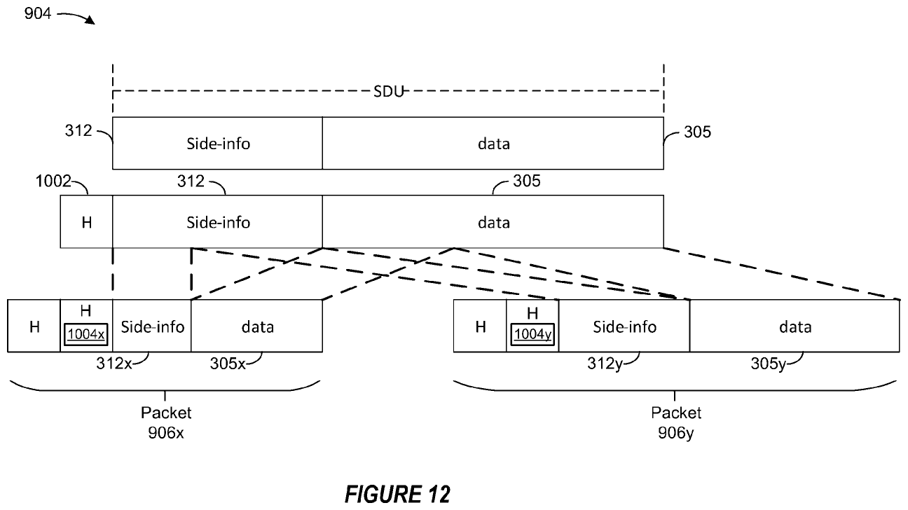

FIG. 12 is a block diagram of an example segmentation operation 904 that supports associating a data segment and a side information segment according to one or more aspects. In FIG. 12, an SDU may include the side information 312 (or a portion thereof) and the data 305 (or a portion thereof). The header 1002 may be added to the SDU, such as to generate a PDCP SDU that includes the header 1002, the side information 312, and the data 305.

In the example of FIG. 12, the side information 312 may be segmented into side information segments 312x, 312y. The data 305 may be segmented into data segments 305x, 305y. In some examples, the side information 312 may be segmented in the same way as the data 305. For example, if the data 305 is segmented, then side information corresponding to the data 305 (such as the side information 312) may also be segmented. After performing such segmentation, a data segment and an associated side information segment may be packetized.

To further illustrate, a packet 906x may include the side information segment 312x and the data segment 305x, and a packet 906y may include the side information segment 312x and the data segment 305x. The packet 906x may include one or more headers (“H”) including an indication (such as the segment offset value 1004x) indicating a position of one or both of the side information segment 312x or the data segment 305x within the packet 906x. The packet 906y may include one or more headers (“H”) including an indication (such as a segment offset value 1004y) indicating a position of one or both of the side information segment 312y or the data segment 305y within the packet 906y.

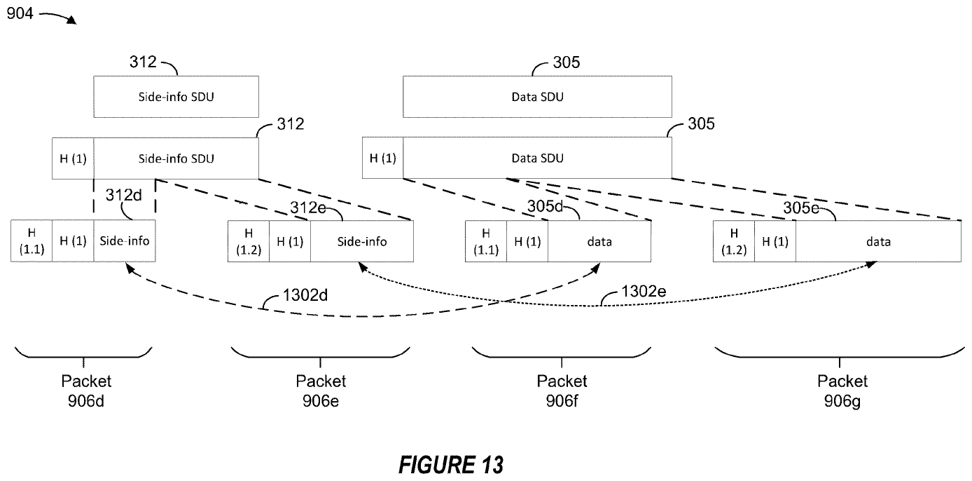

FIG. 12 therefore illustrates an example in which side information and data associated with the side information may be included in a common packet. In some other examples, side information and data associated with the side information may be included in different packets, as described further with reference to the example of FIG. 13.

FIG. 13 is a block diagram of another example segmentation operation 904 that supports associating a data segment and a side information segment according to one or more aspects. In FIG. 13, a first SDU (such as a side information SDU) may include the side information 312, and a second SDU (such as a data SDU) may include the data 305. The side information SDU may be segmented into a packet 906d including a first side information segment 312d of the side information 312 and into a packet 906e including a second side information segment 312e of the side information 312. The data SDU may be segmented into a packet 906f including a first data segment 305d of the data 305 and into a packet 906g including a second data segment 305e of the data 305. As explained with reference to the example of FIG. 12, the side information 312 may be segmented in the same way as the data 305. For example, if the data 305 is segmented, then side information corresponding to the data 305 (such as the side information 312) may also be segmented. After performing such segmentation, a data segment and an associated side information segment may be packetized, such as into the packets 906d-g.

In the example of FIG. 13, side information and data associated with the side information may be included in different packets. To illustrate, the PHY layer 410 may receive a data segment via a first packet that includes the data segment and may receive a side information segment via a second packet that includes the side information segment, where the data segment is associated with the side information segment. In one example, the data segment, the side information segment, the first packet, and the second packet may respectively correspond to the first data segment 305d, the first side information segment 312d, the packet 906f, and the packet 906d. In another example, the data segment, the side information segment, the first packet, and the second packet may respectively correspond to the second data segment 305e, the second side information segment 312e, the packet 906g, and the packet 906e.

In some aspects, a header illustrated in FIG. 13 may include an indication (such as a serial number or other value) that associates side information and data included in different packets. To illustrate, each of the packets 906d, 906f may include a common indication 1302d, which may link or associate the first side information segment 312d with the first data segment 305d. As another example, each of the packets 906e, 906g may include a common indication 1302e, which may link or associate the second side information segment 312e with the second data segment 305e.

In some examples, a first packet may include a first header including a value (such as a serial number or other value), a second packet may include a second header including the value, and the PHY layer 410 may identify, in accordance with the first header and the second header each including the value, that a data segment is associated with a side information segment. For example, the value may correspond to the indication 1302d, the first packet may correspond to the packet 906d, and the second packet may correspond to the packet 906f. In another example, the value may correspond to the indication 1302e, the first packet may correspond to the packet 906e, and the second packet may correspond to the packet 906g.

Further, a packet may include information indicating whether a payload of the packet includes data or side information. In such examples, the first packet may include information indicating that the first packet is associated with a data type (or side information type), and the second packet may indicate that the second packet is associated with a side information type (or a data type).

In some aspects of the disclose, segmenting of data (or side information) may be “mirrored” or “duplicated” to the side information (or the data). For example, referring again to FIG. 9, the encoder device 302 may perform a first segmentation operation 904 to segment one of the data 305 or the side information 312 to generate first segments that include one of a data segment (such as any of the data segments 305a-c) or a side information segment (such as any of the side information segments 312a-c). The encoder device 302 may also perform, in accordance with the first segmentation operation, a second segmentation operation 904 to segment the other of the data or the side information to generate second segments that include the other of the data segment or the side information segment. In some examples, the encoder device 302 may perform the first segmentation operation 904 and the second segmentation operation 904 using the RLC layer 406.

Further, in some aspects of the disclose, assembling of data segments (or side information segments) may be “mirrored” or “duplicated” to the side information segments (or the data segments). For example, the MAC layer 408 may assemble the first segments via a first MAC layer assembling operation may assemble, in accordance with the first MAC layer assembling operation, the second segments.

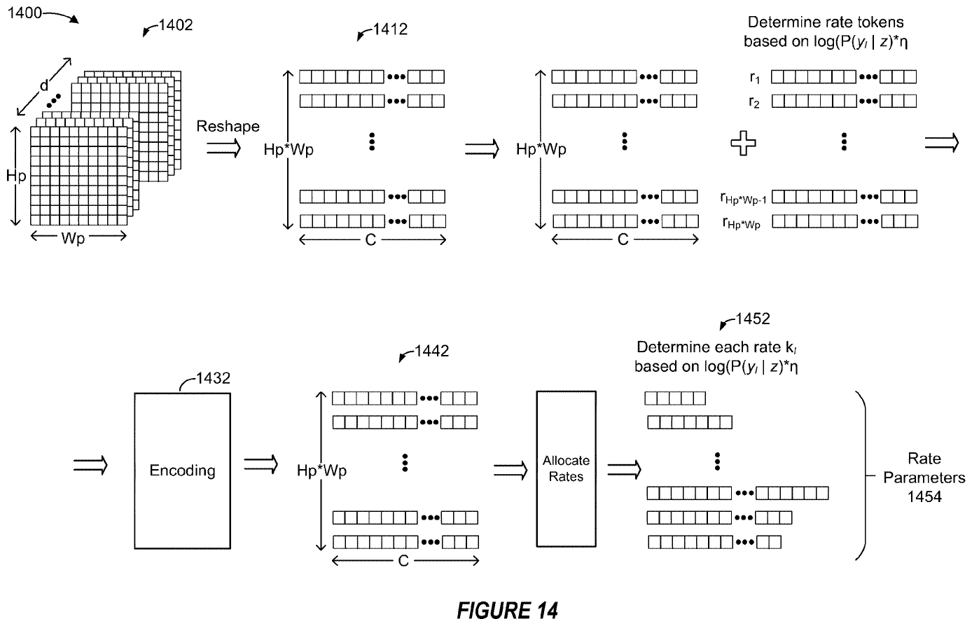

FIG. 14 is a block diagram of an example encoding process 1400 that supports rate parameter recovery according to one or more aspects. In some examples, the encoder device 302 of FIG. 3 may perform the encoding process 1400.

The encoding process 1400 may include receiving data packets 1402. For example, the data packets 1402 may be included in the data 301 of FIG. 3. In FIG. 14, “Wp” may indicate a quantity of data packets in a width direction, “Hp” may indicate a quantity of data packets in a height direction, and “d” may indicate a dimension of each data packet.

The encoding process 1400 may further include reshaping the data packets 1402, at 1412. For example, shaping the data packets 1402 may include lining up the data packets 1402 into a set of rows, where each such row represents one of the data packets, as illustrated in the example of FIG. 14. After reshaping the data packets 1402, the data packets may be associated with a common length “C.”

The encoding process 1400 may also include determining rate tokens, at 1422. The rate tokens may include a positive integer quantity of L rate tokens and may be referred to as r₁, r₂, . . . r_{L}. In some examples, the rate tokens may be determined in accordance with Equation 1:

$${r}_{l} = log ( P ( {y}_{l} \vert z ) * η . \qquad ( Equation 1 )$$

In Equation 1, “log” may indicate a logarithm operation, “P” may indicate a conditional probability, rₗ may indicate the lth rate token, yₗ may indicate an lth output of the semantic encoder 304, z may indicate an output of the hyperprior encoder 308, and η may indicate a channel usage parameter. In some examples, P(yₗ|z) may indicate a feature probability associated with the lth data packet, such as the feature probability 314 of FIG. 3. In some examples, the encoder device 302 may determine channel usage parameter η based on one or more parameters, such as encoder input statistics and a channel quality metric. In some examples, the channel quality metric may be based on a sounding measurement, channel state information (CSI) feedback, or another technique.

The encoding process 1400 may further include an encoding operation (also referred to as a transformation operation), at 1432, to generate transformed data packets 1442. In some examples, the JSCC encoder 306 of FIG. 3 may perform the encoding operation.

The encoding process 1400 may further include performing rate allocation to generate rate-adjusted data packets 1452 based on the encoded data packets 1442. The rate-adjusted data packets 1452 may be associated with rate parameters 1454. In some examples, a rate parameter may also be referred to as a “length” or “rate,” and a data packet may also be referred to as a “message.” Performing the rate allocation may include adjusting lengths of the encoded data packets 1442, such as by truncating the encoded data packets 1442 to generate the rate-adjusted data packets 1452 having sizes corresponding to the rate parameters 1454. In some examples, the rate parameters 1454 may include a positive integer quantity of L rate parameters, and the rate parameters 1454 may be referred to as k₁, k₂, . . . k_{L}. In some examples, the rate parameters 1454 may be determined in accordance with the rate tokens determined at 1422.

The rate-adjusted data packets 1452 may be transmitted to one or more devices, such as to the decoder device 352 via the one or more channels 342 of FIG. 3. In some implementations, the rate-adjusted data packets 1452 may be transmitted via an analog transmission.

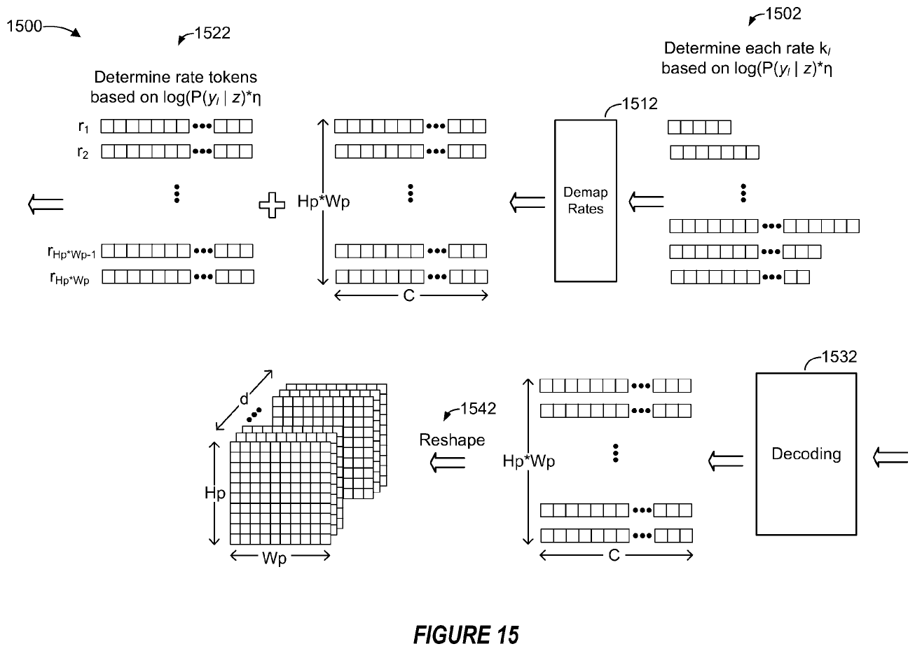

In some aspects of the disclosure, the encoder device 302 may transmit, with the rate-adjusted data packets 1452, rate recovery information to enable the decoder device 352 to determine (or “recover”) the rate parameters 1454 without directly indicating the rate parameters 1454, which may include a relatively large quantity of bits or data. In some examples, the rate recovery information may indicate the channel usage parameter η and the rate parameters 1454. In some other examples, the rate recovery information may indicate the channel usage parameter η and side information associated with the rate-adjusted data packets 1452, such as the side information 312. In such examples, the rate recovery information may optionally further include a total rate (or a total length) associated with the rate-adjusted data packets 1452, as described further with reference to FIG. 15.

FIG. 15 is a block diagram of an example decoding process 1500 that supports rate parameter recovery according to one or more aspects. In some examples, the decoder device 352 of FIG. 3 may perform the decoding process 1500.

The decoding process 1500 may include receiving one or more TBs, at 1502. The one or more TBs may include the rate-adjusted data packets 1452 of FIG. 14. For example, the one or more TBs may include or correspond to the data 316 of FIG. 3 or any of the TBs 582, 584, 784.

The decoding process 1500 may further include performing rate de-mapping, at 1512. The decoding process 1500 may further include determining the rate tokens rₗ, at 1522, performing decoding 1532, and performing a reshaping operation, at 1542. In some implementations, the rate tokens may be determined in accordance with Equation 1. In some examples, the JSCC decoder 354 of FIG. 3 may perform the decoding 1532. In some examples, the performing the reshaping operation 1542 may include generating the data packets illustrated in FIG. 14 at 1402.

To enable generation of the data packets, the decoding process 1500 may also include receiving the rate recovery information of FIG. 14 and using the rate recovery information to determine (or “recover”) the rate parameters 1454 of FIG. 14. The decoder device 352 may use the rate parameters 1454 to determine the “correct” size or length (after decoding) of each data packet.

In a first example of a rate recovery technique, the rate recovery information may indicate the channel usage parameter η and index values respectively associated with the rate parameters 1454. The decoding process 1500 may include accessing, in accordance with the index values, a lookup table to identify the rate parameters 1454. In some examples, the decoding process 1500 may include receiving a common control message configuring the rate recovery information and the lookup table. The common control message may include the same downlink control information (DCI) message or sidelink control information (SCI) message, as illustrative examples. In some other examples, the decoding process 1500 may include receiving a first control message configuring the rate recovery information and receiving a second control message configuring the lookup table.

In accordance with the first example, the decoding process 1500 may include summing the rate parameters 1454 to generate a first value and multiplying the first value by the channel usage parameter η to generate a second value. The second value may correspond to a total number of resource elements (REs) include in the one or more TBs received at 1502. In an illustrative example, the second value may be indicated as L and may be determined in accordance with Equation 2:

$$L = η * {\sum }_{l = 1}^{L} {k}_{i} η * {\sum }_{l = 1}^{L} {k}_{i} . \qquad ( Equation 2 )$$

In such examples, the decoding process 1500 may include determining (or deriving) the total number of REs after determining the rate parameters 1454 and decoding the data packets of the one or more TBs in accordance with the total number of REs and the rate parameters 1454 (such as by performing the rate de-mapping 1512 in accordance with the total number of REs and the rate parameters 1454).

In a second example of a rate recovery technique, the rate recovery information may indicate the channel usage parameter η and side information associated with the data packets, such as the side information 312. In such examples, the decoding process 1500 may include determining the rate parameters 1454 in accordance with the side information. In some implementations, the side information and the one or more TBs may be received via common signaling. Further, the decoding process 1500 may include a control message scheduling the common signaling, where the control message may indicate a modulation and coding scheme (MCS) associated with the side information. To illustrate, the side information may be included in a common PDSCH or PSSCH transmission, and the MCS associated with the side information may be indicated via the common signaling (such as the same DCI or SCI) that schedules the PDSCH or PSSCH transmission.

In a particular implementation of the second example of the rate recovery technique, the rate recovery information may further include a total rate associated with the data packets (such as a sum of the lengths of the data packets). The total rate may be configured via configuration of a total TB size of the one or more TBs.

In a particular implementation of the second example of the rate recovery technique, the decoding process 1500 may include receiving a total TB size N (where N indicates a positive quantity of TBs received at 1502) and receiving an explicit indication of the value of L. By explicitly indicating the value of L, the decoder device 352 may avoid computing L in accordance with Equation 2, above.

One or more implementations aspects described herein may improve performance within a wireless communication system. In some aspects, by avoiding multiplexing packets associated with different encoding processes (such as the encoding processes 502, 504) into the same packet, a wireless communication device may ensure that such a packet includes data of at most one semantic encoding process, which may improve certain operations that utilize a content type of the data, such as a JSCC encoding operation that utilizes the content type for encoding efficiency. Alternatively, or in addition, by indicating that a data segment is associated with a side information segment, the wireless communication device may encode a data segment based on the “correct” side information segment, which may avoid a “mismatch” between non-corresponding segments. Alternatively, or in addition, by using rate recovery information to indicate and recover rate parameters associated with data packets, wireless devices may avoid transmitting and receiving an explicit indication of the rate parameters, which may be relatively large, thus reducing an amount of signaling and wireless resources used in a wireless communication system.

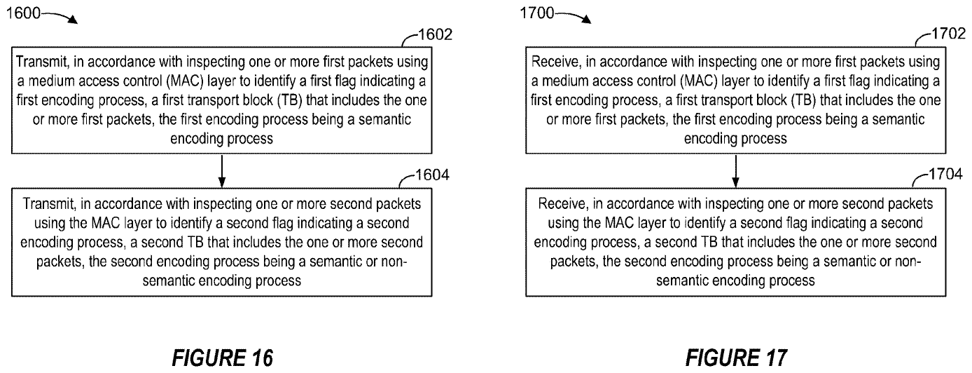

FIG. 16 is a flow diagram illustrating an example process 1600 that supports packet inspection using a MAC layer for a semantic encoding process according to one or more aspects. The process 1600 may be performed by a wireless communication device, such as by the UE 115 or by the base station 105.

At block 1602, the process 1600 includes transmitting, in accordance with inspecting one or more first packets using a medium access control (MAC) layer to identify a first flag indicating a first encoding process, a first transport block (TB) that includes the one or more first packets. The first encoding process is a semantic encoding process. To illustrate, the first flag may be represented as “x” in the PDCP headers 552a-c. The MAC layer may correspond to the MAC layer 408. The first TB may correspond to the first TB 582, and the first encoding process may correspond to the first encoding process 502.

At block 1604, the process 1600 further includes transmitting, in accordance with inspecting one or more second packets using the MAC layer to identify a second flag indicating a second encoding process, a second TB that includes the one or more second packets. The second encoding process is a semantic or non-semantic encoding process. To illustrate, the second flag may be represented as “y” in the PDCP headers 554a-c. The second TB may correspond to the second TB 584 or the second TB 784, and the second encoding process may correspond to the second encoding process 504.

FIG. 17 is a flow diagram illustrating an example process 1700 that supports packet inspection using a MAC layer for a semantic encoding process according to one or more aspects. The process 1700 may be performed by a wireless communication device, such as by the UE 115 or by the base station 105.

At block 1702, the process 1700 includes receiving, in accordance with inspecting one or more first packets using a medium access control (MAC) layer to identify a first flag indicating a first encoding process, a first transport block (TB) that includes the one or more first packets. The first encoding process is a semantic encoding process. To illustrate, the first flag may be represented as “x” in the PDCP headers 552a-c. The MAC layer may correspond to the MAC layer 408. The first TB may correspond to the first TB 582, and the first encoding process may correspond to the first encoding process 502.

At block 1704, the process 1700 further includes receiving, in accordance with inspecting one or more second packets using the MAC layer to identify a second flag indicating a second encoding process, a second TB that includes the one or more second packets. The second encoding process is a semantic or non-semantic encoding process. To illustrate, the second flag may be represented as “y” in the PDCP headers 554a-c. The second TB may correspond to the second TB 584 or the second TB 784, and the second encoding process may correspond to the second encoding process 504.

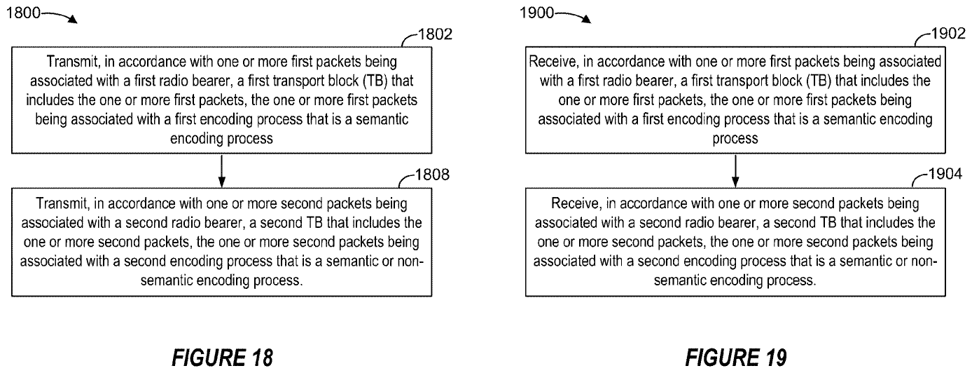

FIG. 18 is a flow diagram illustrating an example process 1800 that supports packet inspection using a MAC layer for a semantic encoding process according to one or more aspects. The process 1800 may be performed by a wireless communication device, such as by the UE 115 or by the base station 105.

At block 1802, the process 1700 includes transmitting, in accordance with one or more first packets being associated with a first radio bearer, a first transport block (TB) that includes the one or more first packets. The one or more first packets are associated with a first encoding process that is a semantic encoding process. To illustrate, the first radio bearer may correspond to the first radio bearer 532. The first TB may correspond to the first TB 582, and the first encoding process may correspond to the first encoding process 502.

At block 1804, the process 1800 further includes transmitting, in accordance with one or more second packets being associated with a second radio bearer, a second TB that includes the one or more second packets. The one or more second packets are associated with a second encoding process that is a semantic or non-semantic encoding process. To illustrate, the second radio bearer may correspond to the second radio bearer 734 or the second radio bearer 834. The second TB may correspond to the second TB 584 or the second TB 784, and the second encoding process may correspond to the second encoding process 504.

FIG. 19 is a flow diagram illustrating an example process 1900 that supports packet inspection using a MAC layer for a semantic encoding process according to one or more aspects. The process 1900 may be performed by a wireless communication device, such as by the UE 115 or by the base station 105.

At block 1902, the process 1900 includes receiving, in accordance with one or more first packets being associated with a first radio bearer, a first transport block (TB) that includes the one or more first packets. The one or more first packets are associated with a first encoding process that is a semantic encoding process. To illustrate, the first radio bearer may correspond to the first radio bearer 532. The first TB may correspond to the first TB 582, and the first encoding process may correspond to the first encoding process 502.

At block 1904, the process 1900 further includes receiving, in accordance with one or more second packets being associated with a second radio bearer, a second TB that includes the one or more second packets. The one or more second packets are associated with a second encoding process that is a semantic or non-semantic encoding process. To illustrate, the second radio bearer may correspond to the second radio bearer 734 or the second radio bearer 834. The second TB may correspond to the second TB 584 or the second TB 784, and the second encoding process may correspond to the second encoding process 504.

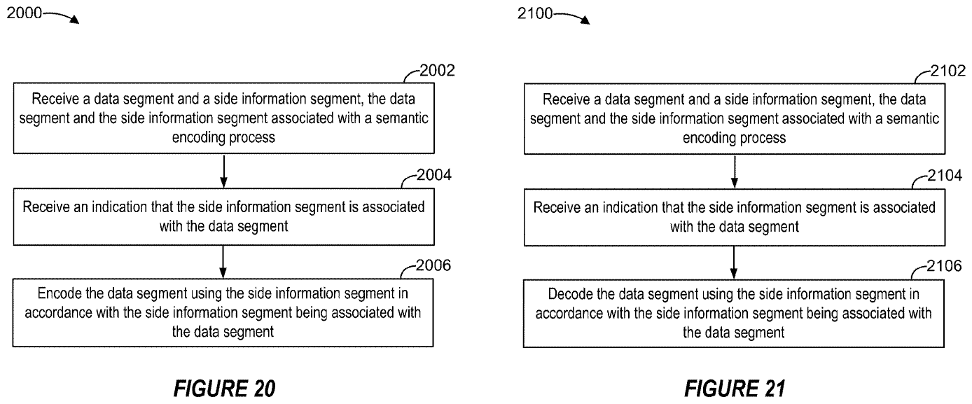

FIG. 20 is a flow diagram illustrating an example process 2000 that supports associating a data segment and a side information segment according to one or more aspects. The process 2000 may be performed by a wireless communication device, such as by the UE 115 or by the base station 105.

At block 2002, the process 2000 includes receiving a data segment and a side information segment. The data segment and the side information segment are associated with a semantic encoding process. For example, the data segment may correspond to one of the data segments 305a-c, and the side information segment may correspond to one of the side information segments 312a-c, respectively. In some examples, the semantic encoding process may correspond to the first encoding process 502 or the second encoding process 504.

At block 2004, the process 2000 includes receiving an indication that the side information segment is associated with the data segment. In some examples, the indication includes or corresponds to the segment offset value 1004. In some other examples, the indication includes or corresponds to the indication 1302d or the indication 1302e.

At block 2006, the process 2000 includes encoding the data segment using the side information segment in accordance with the side information segment being associated with the data segment. For example, one of the JSCC encoders 306a-c may encode one of the data segments 305a-c, respectively, using one of the side information segments 312a-c, respectively.

FIG. 21 is a flow diagram illustrating an example process 2100 that supports associating a data segment and a side information segment according to one or more aspects. The process 2100 may be performed by a wireless communication device, such as by the UE 115 or by the base station 105.

At block 2102, the process 2100 includes receiving a data segment and a side information segment. The data segment and the side information segment are associated with a semantic encoding process. For example, the data segment may correspond to one of the data segments 305a-c, and the side information segment may correspond to one of the side information segments 312a-c, respectively. In some examples, the semantic encoding process may correspond to the first encoding process 502 or the second encoding process 504.

At block 2104, the process 2000 includes receiving an indication that the side information segment is associated with the data segment. In some examples, the indication includes or corresponds to the segment offset value 1004. In some other examples, the indication includes or corresponds to the indication 1302d or the indication 1302e.

At block 2106, the process 2000 includes decoding the data segment using the side information segment in accordance with the side information segment being associated with the data segment. For example, the JSCC decoder 354 may decode one of the data segments 305a-c using one of the side information segments 312a-c, respectively.

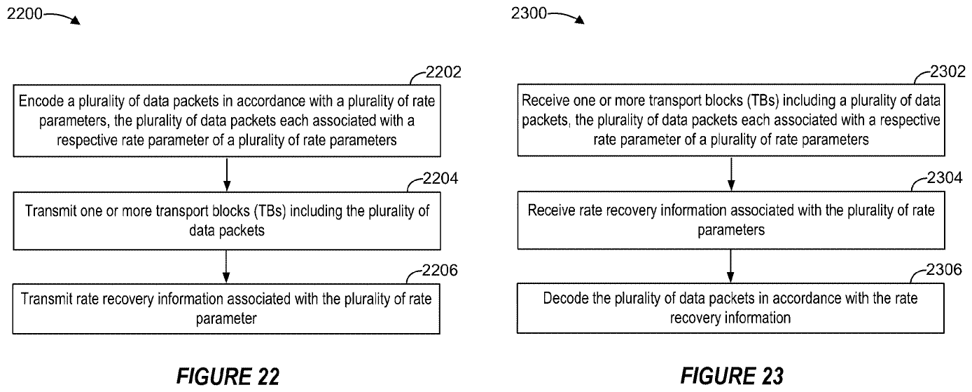

FIG. 22 is a flow diagram illustrating an example process 2200 that supports rate parameter recovery according to one or more aspects. The process 2200 may be performed by a wireless communication device, such as by the UE 115 or by the base station 105.

At block 2202, the process 2200 includes encoding a plurality of data packets in accordance with a plurality of rate parameters. The plurality of data packets are each associated with a respective rate parameter of a plurality of rate parameters. For example, the plurality of data packets may include the rate-adjusted data packets 1452, and the plurality of rate parameters may include the rate parameters 1454.

At block 2204, the process 2200 further includes transmitting one or more transport blocks (TBs) including the plurality of data packets. For example, the one or more TBs may include one or both of the TBs 582, 584.

At block 2206, the process 2200 further includes transmitting rate recovery information associated with the plurality of rate parameters. For example, the rate recovery information may include any of the rate recovery information described with reference to FIGS. 14 and 15.

FIG. 23 is a flow diagram illustrating an example process 2300 that supports rate parameter recovery according to one or more aspects. The process 2300 may be performed by a wireless communication device, such as by the UE 115 or by the base station 105.

At block 2302, the process 2300 includes receiving one or more transport blocks (TBs) including a plurality of data packets. The plurality of data packets are each associated with a respective rate parameter of a plurality of rate parameters. For example, the plurality of data packets may include the rate-adjusted data packets 1452, and the plurality of rate parameters may include the rate parameters 1454. In some examples, the one or more TBs may include one or both of the TBs 582, 584.

At block 2304, the process 2300 further includes receiving rate recovery information associated with the plurality of rate parameters. For example, the rate recovery information may include any of the rate recovery information described with reference to FIGS. 14 and 15.

At block 2306, the process 2300 further includes decoding the plurality of data packets in accordance with the rate recovery information. For example, the rate de-mapping 1512 of FIG. 12 may be performed using the rate recovery information, such as to recover the rates (also referred to herein as lengths or sizes) of the plurality of data packets.

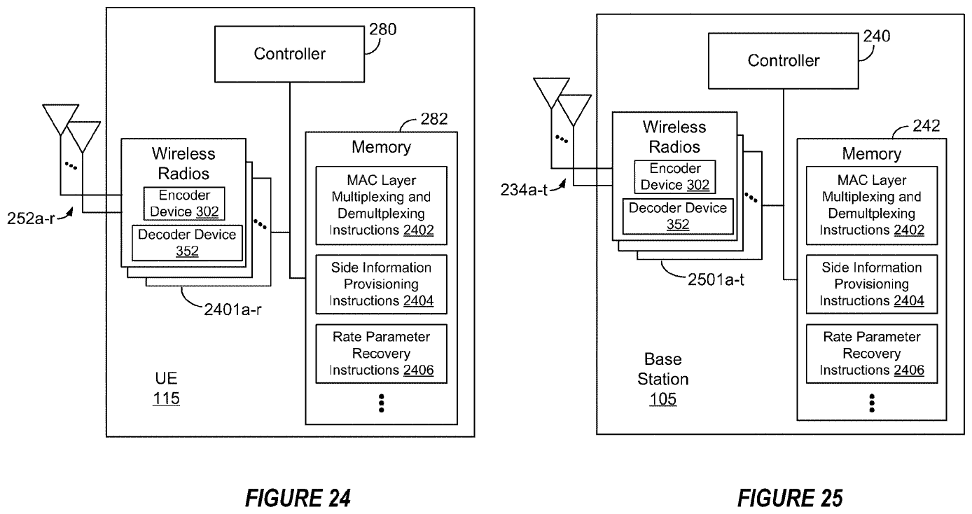

FIG. 24 is a block diagram of an example UE 115 that supports one or more of packet inspection using a MAC layer for a semantic encoding process, associating a data segment and a side information segment, or rate parameter recovery according to one or more aspects. The UE 115 may include structure, hardware, or components described herein. For example, the UE 115 may include the controller 280, which may execute instructions stored in the memory 282. Using the controller 280, the UE 115 may transmit and receive signals via wireless radios 2401a-r and antennas 252a-r. The wireless radios 2401a-r may include one or more components or devices described herein, such as the modulator/demodulators 254a-r, the MIMO detector 256, the receive processor 258, the transmit processor 264, the TX MIMO processor 266, the encoder device 302, the decoder device 352, one or more other components or devices, or a combination thereof.

In some examples, the memory 282 may store instructions executable by one or more processors (e.g., the controller 280) to initiate, perform, or control one or more operations described herein. For example, the memory 282 may store MAC layer multiplexing and demultiplexing instructions 2402 executable by the controller 280 to perform one or more operations described with reference to FIGS. 5-9, one or more operations of one or more of the processes 1600, 1700, 1800, and 1900, or a combination thereof. Alternatively or in addition, the memory 282 may store side information provisioning instructions 2404 executable by the controller 280 to perform one or more operations described with reference to FIGS. 9-13, one or more operations of one or more of the processes 2000 and 2100, or a combination thereof. Alternatively or in addition, the memory 282 may store rate parameter recovery instructions 2406 executable by the controller 280 to perform one or more operations described with reference to FIGS. 14 and 15, one or more operations of one or more of the processes 2200 and 2300, or a combination thereof.

FIG. 25 is a block diagram of an example base station 105 that supports one or more of packet inspection using a MAC layer for a semantic encoding process, associating a data segment and a side information segment, or rate parameter recovery according to one or more aspects. The base station 105 may include structure, hardware, and components described herein. For example, the base station 105 may include the controller 240, which may execute instructions stored in memory 242. Under control of the controller 240, the base station 105 may transmit and receive signals via wireless radios 2501a-t and antennas 234a-t. The wireless radios 2501a-t may include one or more components or devices described herein, such as the modulator/demodulators 232a-t, the MIMO detector 236, the receive processor 238, the transmit processor 220, the TX MIMO processor 230, the encoder device 302, the decoder device 352, one or more other components or devices, or a combination thereof.

In some examples, the memory 242 may store instructions executable by one or more processors (e.g., the controller 240) to initiate, perform, or control one or more operations described herein. For example, the memory 242 may store MAC layer multiplexing and demultiplexing instructions 2402 executable by the controller 240 to perform one or more operations described with reference to FIGS. 5-9, one or more operations of one or more of the processes 1600, 1700, 1800, and 1900, or a combination thereof. Alternatively or in addition, the memory 242 may store side information provisioning instructions 2404 executable by the controller 240 to perform one or more operations described with reference to FIGS. 9-13, one or more operations of one or more of the processes 2000 and 2100, or a combination thereof. Alternatively or in addition, the memory 242 may store rate parameter recovery instructions 2406 executable by the controller 240 to perform one or more operations described with reference to FIGS. 14 and 15, one or more operations of one or more of the processes 2200 and 2300, or a combination thereof.

According to some further aspects, in a first aspect, a wireless communication device includes a processing system. The processing system includes processor circuitry and memory circuitry that stores code and is coupled with the processor circuitry. The processing system is configured to cause the wireless communication device to transmit, in accordance with inspecting one or more first packets using a medium access control (MAC) layer to identify a first flag indicating a first encoding process, a first transport block (TB) that includes the one or more first packets. The first encoding process is a semantic encoding process. The processing system is further configured to cause the wireless communication device to transmit, in accordance with inspecting one or more second packets using the MAC layer to identify a second flag indicating a second encoding process, a second TB that includes the one or more second packets. The second encoding process is a semantic or non-semantic encoding process.

In a second aspect alternatively or in addition to the first aspect, each packet of the one or more first packets includes a first header including the first flag, and each packet of the one or more second packets includes a second header including the second flag.

In a third aspect alternatively or in addition to one or more of the first through second aspects, the first header and the second header are packet data convergence protocol (PDCP) headers associated with a PDCP layer.

In a fourth aspect alternatively or in addition to one or more of the first through third aspects, the first flag is associated with an indexing of semantic packets included in the one or more first packets.

In a fifth aspect alternatively or in addition to one or more of the first through fourth aspects, the one or more first packets and the one or more second packets include medium access control service data units (MAC SDUs). In a sixth aspect alternatively or in addition to one or more of the first through fifth aspects, the processing system is further configured to cause the wireless communication device to generate a first medium access control packet data unit (MAC PDU) that includes the one or more first packets and to generate a second MAC PDU that includes the one or more second packets. The first TB includes the first MAC PDU, and the second TB includes the second MAC PDU.

In a seventh aspect alternatively or in addition to one or more of the first through sixth aspects, the one or more first packets are further associated with a semantic type flag, and the first TB is transmitted via a dedicated radio bearer that is associated with the semantic type flag.

In an eighth aspect alternatively or in addition to one or more of the first through seventh aspects, the one or more first packets are associated with a first logical channel that is reserved for semantically encoded data, and the one or more second packets are associated with a second logical channel that is reserved for non-semantically encoded data.

In a ninth aspect alternatively or in addition to one or more of the first through eighth aspects, the processing system is further configured to cause the wireless communication device to assign, using the MAC layer, the one or more first packets to a first medium access control packet data unit (MAC PDU) in accordance with the one or more first packets being associated with the first logical channel reserved for the semantically encoded data, and to assign, using the MAC layer, the one or more second packets to a second MAC PDU instead of the first MAC PDU in accordance with the one or more second packets being associated with the second logical channel reserved for the non-semantically encoded data.

In a tenth aspect alternatively or in addition to one or more of the first through ninth aspects, the first logical channel is associated with a first logical channel group (LCG) associated with the semantically encoded data, and the second logical channel is associated with a second LCG that is associated with non-semantically encoded data and that is not multiplexed with the first logical channel.

In an eleventh aspect alternatively or in addition to one or more of the first through tenth aspects, a method for wireless communication by a wireless communication device includes transmitting, in accordance with inspecting one or more first packets using a medium access control (MAC) layer to identify a first flag indicating a first encoding process, a first transport block (TB) that includes the one or more first packets, the first encoding process being a semantic encoding process. The method further includes transmitting, in accordance with inspecting one or more second packets using the MAC layer to identify a second flag indicating a second encoding process, a second TB that includes the one or more second packets, the second encoding process being a semantic or non-semantic encoding process.

In a twelfth aspect alternatively or in addition to one or more of the first through eleventh aspects, each packet of the one or more first packets includes a first header including the first flag, and each packet of the one or more second packets includes a second header including the second flag.

In a thirteenth aspect alternatively or in addition to one or more of the first through twelfth aspects, the first header and the second header are packet data convergence protocol (PDCP) headers associated with a PDCP layer.

In a fourteenth aspect alternatively or in addition to one or more of the first through thirteenth aspects, the first flag is associated with an indexing of semantic packets included in the one or more first packets.

In a fifteenth aspect alternatively or in addition to one or more of the first through fourteenth aspects, the one or more first packets and the one or more second packets include medium access control service data units (MAC SDUs).

In a sixteenth aspect alternatively or in addition to one or more of the first through fifteenth aspects, the method further includes generating a first medium access control packet data unit (MAC PDU) that includes the one or more first packets and generating a second MAC PDU that includes the one or more second packets. The first TB includes the first MAC PDU, and the second TB includes the second MAC PDU.

In a seventeenth aspect alternatively or in addition to one or more of the first through sixteenth aspects, the one or more first packets are further associated with a semantic type flag, and the first TB is transmitted via a dedicated radio bearer that is associated with the semantic type flag.

In an eighteenth aspect alternatively or in addition to one or more of the first through seventeenth aspects, the one or more first packets are associated with a first logical channel that is reserved for semantically encoded data, and the one or more second packets are associated with a second logical channel that is reserved for non-semantically encoded data.

In a nineteenth aspect alternatively or in addition to one or more of the first through eighteenth aspects, the method further includes assigning, using the MAC layer, the one or more first packets to a first medium access control packet data unit (MAC PDU) in accordance with the one or more first packets being associated with the first logical channel reserved for the semantically encoded data and assigning, using the MAC layer, the one or more second packets to a second MAC PDU instead of the first MAC PDU in accordance with the one or more second packets being associated with the second logical channel reserved for the non-semantically encoded data.

In a twentieth aspect alternatively or in addition to one or more of the first through nineteenth aspects, the first logical channel is associated with a first logical channel group (LCG) associated with the semantically encoded data, and the second logical channel is associated with a second LCG that is associated with non-semantically encoded data and that is not multiplexed with the first logical channel.

In a twenty-first aspect alternatively or in addition to one or more of the first through twentieth aspects, a wireless communication device includes a processing system. The processing system includes processor circuitry and memory circuitry that stores code and is coupled with the processor circuitry. The processing system is configured to cause the wireless communication device to transmit, in accordance with one or more first packets being associated with a first radio bearer, a first TB that includes the one or more first packets and to transmit, in accordance with one or more second packets being associated with a second radio bearer, a second TB that includes the one or more second packets. The one or more first packets are associated with a first encoding process that is a semantic encoding process, and the one or more second packets are associated with a second encoding process that is a semantic or non-semantic encoding process.

In a twenty-second aspect alternatively or in addition to one or more of the first through twenty-first aspects, the processing system is further configured to cause the wireless communication device to assign, in accordance with the first radio bearer and the second radio bearer, the one or more first packets and the one or more second packets to different respective medium access control packet data units (MAC PDUs).

In a twenty-third aspect alternatively or in addition to one or more of the first through twenty-second aspects, the processing system is further configured to cause the wireless communication device to generate quality of service (QoS) data associated with the one or more first packets, the QoS data including a semantic type flag indicating that the first encoding process is the semantic encoding process.

In a twenty-fourth aspect alternatively or in addition to one or more of the first through twenty-third aspects, the one or more first packets and the one or more second packets include medium access control service data units (MAC SDUs).

In a twenty-fifth aspect alternatively or in addition to one or more of the first through twenty-fourth aspects, the processing system is further configured to cause the wireless communication device to generate a first medium access control packet data unit (MAC PDU) that includes the one or more first packets and to generate a second MAC PDU that includes the one or more second packets. The the first TB includes the first MAC PDU, and the second TB includes the second MAC PDU.

In a twenty-sixth aspect alternatively or in addition to one or more of the first through twenty-fifth aspects, a method for wireless communication by a wireless communication device includes transmitting, in accordance with one or more first packets being associated with a first radio bearer, a first transport block (TB) that includes the one or more first packets. The one or more first packets are associated with a first encoding process that is a semantic encoding process. The method further includes transmitting, in accordance with one or more second packets being associated with a second radio bearer, a second TB that includes the one or more second packets. The one or more second packets are associated with a second encoding process that is a semantic or non-semantic encoding process.

In a twenty-seventh aspect alternatively or in addition to one or more of the first through twenty-sixth aspects, the method further includes assigning, in accordance with the first radio bearer and the second radio bearer, the one or more first packets and the one or more second packets to different respective medium access control packet data units (MAC PDUs).

In a twenty-eighth aspect alternatively or in addition to one or more of the first through twenty-seventh aspects, the method further includes generating quality of service (QoS) data associated with the one or more first packets, the QoS data including a semantic type flag indicating that the first encoding process is the semantic encoding process.

In a twenty-ninth aspect alternatively or in addition to one or more of the first through twenty-eighth aspects, the one or more first packets and the one or more second packets include medium access control service data units (MAC SDUs).

In a thirtieth aspect alternatively or in addition to one or more of the first through twenty-ninth aspects, the method further includes generating a first medium access control packet data unit (MAC PDU) that includes the one or more first packets and generating a second MAC PDU that includes the one or more second packets. The the first TB includes the first MAC PDU, and the second TB includes the second MAC PDU.

Those of skill in the art would understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

One or more components, functional blocks, and modules described herein may include processors, electronics devices, hardware devices, electronics components, logical circuits, memories, software codes, firmware codes, among other examples, or any combination thereof. Software shall be construed broadly to mean instructions, instruction sets, code, code segments, program code, programs, subprograms, software modules, application, software applications, software packages, routines, subroutines, objects, executables, threads of execution, procedures, and/or functions, among other examples, whether referred to as software, firmware, middleware, microcode, hardware description language or otherwise. In addition, features discussed herein may be implemented via specialized processor circuitry, via executable instructions, or combinations thereof.

The various illustrative logics, logical blocks, modules, circuits and algorithm processes described in connection with the implementations disclosed herein may be implemented as electronic hardware, computer software, or combinations of both. The interchangeability of hardware and software has been described generally, in terms of functionality, and illustrated in the various illustrative components, blocks, modules, circuits and processes described above. Whether such functionality is implemented in hardware or software depends upon the particular application and design of the overall system.

A hardware and data processing apparatus used to implement one or more various illustrative logics, logical blocks, modules and circuits described in connection with the aspects disclosed herein may be implemented or performed with a general purpose single- or multi-chip processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general purpose processor may be a microprocessor, or, any conventional processor, controller, microcontroller, or state machine. In some implementations, a processor may be implemented as a combination of computing devices, such as a combination of a DSP and a microprocessor, a plurality of microprocessors, one or more microprocessors in conjunction with a DSP core, or any other such configuration. In some implementations, particular processes and methods may be performed by circuitry that is specific to a given function.

In one or more aspects, one or more functions described may be implemented in hardware, digital electronic circuitry, computer software, firmware, including the structures disclosed in this specification and their structural equivalents thereof, or in any combination thereof. Implementations of the subject matter described in this specification also can be implemented as one or more computer programs, that is one or more modules of computer program instructions, encoded on a computer storage media for execution by, or to control the operation of, data processing apparatus.

If implemented in software, one or more functions may be stored on or transmitted over as one or more instructions or code on a computer-readable medium. The processes of a method or algorithm disclosed herein may be implemented in a processor-executable software module which may reside on a computer-readable medium. Computer-readable media includes both computer storage media and communication media including any medium that can be enabled to transfer a computer program from one place to another. A storage media may be any available media that may be accessed by a computer. By way of example, and not limitation, such computer-readable media may include RAM, ROM, EEPROM, CD-ROM or other optical disk storage, magnetic disk storage or other magnetic storage devices, or any other medium that may be used to store desired program code in the form of instructions or data structures and that may be accessed by a computer. Disk and disc, as used herein, includes compact disc (CD), laser disc, optical disc, digital versatile disc (DVD), floppy disk, and Blu-ray disc where disks usually reproduce data magnetically, while discs reproduce data optically with lasers. Combinations of the above should also be included within the scope of computer-readable media. Additionally, the operations of a method or algorithm may reside as one or any combination or set of codes and instructions on a machine readable medium and computer-readable medium, which may be incorporated into a computer program product.

Various modifications to the implementations described in this disclosure may be readily apparent to those skilled in the art, and the generic principles defined herein may be applied to some other implementations without departing from the spirit or scope of this disclosure. Thus, the claims are not intended to be limited to the implementations shown herein, but are to be accorded the widest scope consistent with this disclosure, the principles and the novel features disclosed herein.

Additionally, a person having ordinary skill in the art will readily appreciate, the terms “upper” and “lower” are sometimes used for ease of describing the figures, and indicate relative positions corresponding to the orientation of the figure on a properly oriented page, and may not reflect the proper orientation of any device as implemented.

Certain features that are described in this specification in the context of separate implementations also can be implemented in combination in a single implementation. Conversely, various features that are described in the context of a single implementation also can be implemented in multiple implementations separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. Further, the drawings may schematically depict one more example processes in the form of a flow diagram. However, other operations that are not depicted can be incorporated in the example processes that are schematically illustrated. For example, one or more additional operations can be performed before, after, simultaneously, or between any of the illustrated operations. In certain circumstances, multitasking and parallel processing may be advantageous. Moreover, the separation of various system components in the implementations described above should not be understood as requiring such separation in all implementations, and it should be understood that the described program components and systems can generally be integrated together in a single software product or packaged into multiple software products. Additionally, some other implementations are within the scope of the following claims. In some cases, the actions recited in the claims can be performed in a different order and still achieve desirable results.

As used herein, including in the claims, the term “or,” when used in a list of two or more items, means that any one of the listed items can be employed by itself, or any combination of two or more of the listed items can be employed. For example, if a composition is described as containing components A, B, or C, the composition can contain A alone; B alone; C alone; A and B in combination; A and C in combination; B and C in combination; or A, B, and C in combination. Also, as used herein, including in the claims, “or” as used in a list of items prefaced by “at least one of” indicates a disjunctive list such that, for example, a list of “at least one of A, B, or C” means A or B or C or AB or AC or BC or ABC (that is A and B and C) or any of these in any combination thereof. The term “substantially” is defined as largely but not necessarily wholly what is specified (and includes what is specified; for example, substantially 90 degrees includes 90 degrees and substantially parallel includes parallel), as understood by a person of ordinary skill in the art. In any disclosed implementations, the term “substantially” may be substituted with “within [a percentage] of” what is specified, where the percentage includes 0.1, 1, 5, or 10 percent.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples and designs described herein but is to be accorded the widest scope consistent with the principles and novel features disclosed herein.

1. A wireless communication device comprising:
a processing system that includes processor circuitry and memory circuitry that stores code and is coupled with the processor circuitry, the processing system configured to cause the wireless communication device to:
transmit, in accordance with inspecting one or more first packets using a medium access control (MAC) layer to identify a first flag indicating a first encoding process, a first transport block (TB) that includes the one or more first packets, the first encoding process being a semantic encoding process; and
transmit, in accordance with inspecting one or more second packets using the MAC layer to identify a second flag indicating a second encoding process, a second TB that includes the one or more second packets, the second encoding process being a semantic or non-semantic encoding process.

2. The wireless communication device of claim 1, wherein each packet of the one or more first packets includes a first header including the first flag, and wherein each packet of the one or more second packets includes a second header including the second flag.

3. (canceled)

4. The wireless communication device of claim 1, wherein the first flag is associated with an indexing of semantic packets included in the one or more first packets.

5. The wireless communication device of claim 1, wherein the one or more first packets and the one or more second packets include medium access control service data units (MAC SDUs).

6. The wireless communication device of claim 1, wherein the processing system is further configured to cause the wireless communication device to:
generate a first medium access control packet data unit (MAC PDU) that includes the one or more first packets, wherein the first TB includes the first MAC PDU; and
generate a second MAC PDU that includes the one or more second packets, wherein the second TB includes the second MAC PDU.

7. The wireless communication device of claim 1, wherein the one or more first packets are further associated with a semantic type flag, and wherein the first TB is transmitted via a dedicated radio bearer that is associated with the semantic type flag.

8. The wireless communication device of claim 1, wherein the one or more first packets are associated with a first logical channel that is reserved for semantically encoded data, and wherein the one or more second packets are associated with a second logical channel that is reserved for non-semantically encoded data.

9. The wireless communication device of claim 8, wherein the processing system is further configured to cause the wireless communication device to:
assign, using the MAC layer, the one or more first packets to a first medium access control packet data unit (MAC PDU) in accordance with the one or more first packets being associated with the first logical channel reserved for the semantically encoded data; and
assign, using the MAC layer, the one or more second packets to a second MAC PDU instead of the first MAC PDU in accordance with the one or more second packets being associated with the second logical channel reserved for the non-semantically encoded data.

10. The wireless communication device of claim 8, wherein the first logical channel is associated with a first logical channel group (LCG) associated with the semantically encoded data, and wherein the second logical channel is associated with a second LCG that is associated with non-semantically encoded data and that is not multiplexed with the first logical channel.

11. A method for wireless communication by a wireless communication device, the method comprising:
transmitting, in accordance with inspecting one or more first packets using a medium access control (MAC) layer to identify a first flag indicating a first encoding process, a first transport block (TB) that includes the one or more first packets, the first encoding process being a semantic encoding process; and
transmitting, in accordance with inspecting one or more second packets using the MAC layer to identify a second flag indicating a second encoding process, a second TB that includes the one or more second packets, the second encoding process being a semantic or non-semantic encoding process.

12. The method of claim 11, wherein each packet of the one or more first packets includes a first header including the first flag, and wherein each packet of the one or more second packets includes a second header including the second flag.

13. (canceled)

14. The method of claim 11, wherein the first flag is associated with an indexing of semantic packets included in the one or more first packets.

15. (canceled)

16. The method of claim 11, further comprising:
generating a first medium access control packet data unit (MAC PDU) that includes the one or more first packets, wherein the first TB includes the first MAC PDU; and
generating a second MAC PDU that includes the one or more second packets, wherein the second TB includes the second MAC PDU.

17. The method of claim 11, wherein the one or more first packets are further associated with a semantic type flag, and wherein the first TB is transmitted via a dedicated radio bearer that is associated with the semantic type flag.

18. The method of claim 11, wherein the one or more first packets are associated with a first logical channel that is reserved for semantically encoded data, and wherein the one or more second packets are associated with a second logical channel that is reserved for non-semantically encoded data.

19. (canceled)

20. (canceled)

21. A wireless communication device comprising:
a processing system that includes processor circuitry and memory circuitry that stores code and is coupled with the processor circuitry, the processing system configured to cause the wireless communication device to:
transmit, in accordance with one or more first packets being associated with a first radio bearer, a first transport block (TB) that includes the one or more first packets, the one or more first packets being associated with a first encoding process that is a semantic encoding process; and
transmit, in accordance with one or more second packets being associated with a second radio bearer, a second TB that includes the one or more second packets, the one or more second packets being associated with a second encoding process that is a semantic or non-semantic encoding process.

22. The wireless communication device of claim 21, wherein the processing system is further configured to cause the wireless communication device to assign, in accordance with the first radio bearer and the second radio bearer, the one or more first packets and the one or more second packets to different respective medium access control packet data units (MAC PDUs).

23. The wireless communication device of claim 21, wherein the processing system is further configured to cause the wireless communication device to generate quality of service (QoS) data associated with the one or more first packets, the QoS data including a semantic type flag indicating that the first encoding process is the semantic encoding process.

24. The wireless communication device of claim 21, wherein the one or more first packets and the one or more second packets include medium access control service data units (MAC SDUs).

25. The wireless communication device of claim 21, wherein the processing system is further configured to cause the wireless communication device to:
generate a first medium access control packet data unit (MAC PDU) that includes the one or more first packets, wherein the first TB includes the first MAC PDU; and
generate a second MAC PDU that includes the one or more second packets, wherein the second TB includes the second MAC PDU.

26-30. (canceled)
